(19) United States
(12) Patent Application Publication
(10) Pub. No.: US 2023/0395580 A1
(43) Pub. Date: Dec. 7, 2023

(54) STACKED SEMICONDUCTOR PACKAGE AND METHOD OF MANUFACTURING THE SAME

(71) Applicant: Murata Manufacturing Co., Ltd., Kyoto-fu (JP)

(72) Inventor: Yoshimasa YOSHIOKA, Nagaokakyo-shi (JP)

(73) Assignee: Murata Manufacturing Co., Ltd., Kyoto-fu (JP)

(21) Appl. No.: 18/323,376

(22) Filed: May 24, 2023

(30) Foreign Application Priority Data
Jun. 2, 2022 (JP) 2022-090321

(51) Int. Cl. H01L 25/16; H01L 23/00

(52) U.S. Cl. CPC H01L 25/16; H01L 24/08; H01L 24/80; H01L 24/16; H01F 27/2804

(57) ABSTRACT

A stacked semiconductor package includes a first substrate; a three-dimensional device stacked in a first direction with respect to the first substrate; and a first connection member for connecting the first substrate to the three-dimensional device. The three-dimensional device includes components, each of which includes a semiconductor integrated circuit component and a passive component stacked in the first direction. A first major surface, which faces the three-dimensional device, of the first substrate and a first major surface, which faces the first substrate, of the three-dimensional device are connected to each other with the first connection member interposed therebetween while being separated from each other. A first major surface, which faces the passive component, of the semiconductor integrated circuit component and a first major surface, which faces the semiconductor integrated circuit component, of the passive component each include a flat surface.

### CROSS-REFERENCE TO RELATED APPLICATION

This application claims benefit of priority to Japanese Patent Application No. 2022-090321, filed Jun. 2, 2022, the entire content of which is incorporated herein by reference.

### BACKGROUND

### Technical Field

The present disclosure relates to a stacked semiconductor package and a method of manufacturing the same.

### Background Art

In recent years, with the miniaturization and performance improvement of stacked semiconductor packages, the integration of electronic circuits has been further advanced. Hitherto, as stacked semiconductor packages, a stacked semiconductor package is described in Japanese Patent No. 5448393. This stacked semiconductor package includes a first semiconductor package, a second semiconductor package stacked on the first semiconductor package, and a capacitor provided between the first semiconductor package and the second semiconductor package and connected to the first semiconductor package and the second semiconductor package. With the first semiconductor package, the second semiconductor package, and the capacitor stacked in this way, the footprint (the area of the circuit or component) is small.

### SUMMARY

However, in the related-art stacked semiconductor package, the overall thickness of the stacked semiconductor package is large since the first semiconductor package, the second semiconductor package, and the capacitor are connected to each other by using solder balls or a solder paste, and it is thus difficult to achieve a reduction in thickness.

Therefore, the present disclosure provides a stacked semiconductor package and a method of manufacturing the same that can achieve a reduction in thickness.

A stacked semiconductor package according to an aspect of the present disclosure includes a first substrate; a three-dimensional device stacked in a first direction with respect to the first substrate; and a first connection member for connecting the first substrate to the three-dimensional device. The three-dimensional device includes a plurality of components each of which includes a semiconductor integrated circuit component and a passive component stacked in the first direction. A first major surface, which faces the three-dimensional device, of the first substrate and a first major surface, which faces the first substrate, of the three-dimensional device are connected to each other with the first connection member interposed therebetween while being separated from each other. A first major surface, which faces the passive component, of the semiconductor integrated circuit component and a first major surface, which faces the semiconductor integrated circuit component of the passive component each include a flat surface. The flat surface of the semiconductor integrated circuit component and the flat surface of the passive component are bonded together while being in contact with each other.

According to the aspect, since the flat surface of the semiconductor integrated circuit component and the flat surface of the passive component are bonded together while being in contact with each other, the thickness of the three-dimensional device can be reduced so that a reduction in the thickness of the stacked semiconductor package can be achieved.

It is preferred that an embodiment of a method of manufacturing a stacked semiconductor package includes forming a three-dimensional device by bonding a semiconductor integrated circuit component that has a flat surface to a passive component that has a flat surface while holding the flat surfaces in contact with each other; and connecting a first major surface of the three-dimensional device to a first major surface of a first substrate with a connection member interposed therebetween while separating the first major surfaces from each other.

According to the embodiment, since the flat surface of the semiconductor integrated circuit component and the flat surface of the passive component are bonded together while being in contact with each other, the thickness of the three-dimensional device can be reduced so that a reduction in the thickness of a stacked semiconductor package can be achieved.

With the stacked semiconductor package and the method of manufacturing the same according to the aspects of the present disclosure, a reduction in thickness can be achieved.

### BRIEF DESCRIPTION OF THE DRAWINGS

FIG. 1 is a schematic sectional view illustrating a first embodiment of a stacked semiconductor package;

FIG. 2A is a schematic sectional view for describing a method of manufacturing a stacked semiconductor package;

FIG. 2B is a schematic sectional view for describing the method of manufacturing a stacked semiconductor package;

FIG. 2C is a schematic sectional view for describing the method of manufacturing a stacked semiconductor package;

FIG. 2D is a schematic sectional view for describing the method of manufacturing a stacked semiconductor package;

FIG. 2E is a schematic sectional view for describing the method of manufacturing a stacked semiconductor package;

FIG. 2F is a schematic sectional view for describing the method of manufacturing a stacked semiconductor package;

FIG. 2G is a schematic sectional view for describing the method of manufacturing a stacked semiconductor package;

FIG. 3A is a schematic sectional view for describing a modification of a method of manufacturing a stacked semiconductor package;

FIG. 3B is a schematic sectional view for describing the modification of the method of manufacturing a stacked semiconductor package;

FIG. 3C is a schematic sectional view for describing the modification of the method of manufacturing a stacked semiconductor package;

FIG. 4 is a schematic bottom view of an inductor component 3 when viewed from the bottom surface side;

FIG. 5 is a sectional view taken along the line V-V of FIG. 4;

FIG. 6 is a sectional view taken along the line VI-VI of FIG. 4;

FIG. 7A is a schematic sectional view for describing a method of manufacturing an inductor component;

FIG. 7B is a schematic sectional view for describing the method of manufacturing an inductor component;

FIG. 7C is a schematic sectional view for describing the method of manufacturing an inductor component;

FIG. 7D is a schematic sectional view for describing the method of manufacturing an inductor component;

FIG. 7E is a schematic sectional view for describing the method of manufacturing an inductor component;

FIG. 7F is a schematic sectional view for describing the method of manufacturing an inductor component;

FIG. 7G is a schematic sectional view for describing the method of manufacturing an inductor component;

FIG. 7H is a schematic sectional view for describing the method of manufacturing an inductor component;

FIG. 7I is a schematic sectional view for describing the method of manufacturing an inductor component;

FIG. 7J is a schematic sectional view for describing the method of manufacturing an inductor component;

FIG. 7K is a schematic sectional view for describing the method of manufacturing an inductor component;

FIG. 8 is a simplified sectional view illustrating a first modification of a stacked semiconductor package;

FIG. 9 is a simplified sectional view illustrating a second modification of a stacked semiconductor package;

FIG. 10A is a simplified sectional view illustrating a second embodiment of a stacked semiconductor package;

FIG. 10B is a simplified plan view illustrating the second embodiment of the stacked semiconductor package;

FIG. 11 is a simplified sectional view illustrating a modification of a stacked semiconductor package; and

FIG. 12 is a simplified sectional view illustrating a third embodiment of a stacked semiconductor package.

### DETAILED DESCRIPTION

Now, a stacked semiconductor package and a method of manufacturing the same according to aspects of the present disclosure will be described in more detail with embodiments illustrated in the drawings. Note that, some of the drawings are schematic and does not necessarily reflect actual dimensions or ratios.

### First Embodiment

1. Schematic Configuration

Configuration of Stacked Semiconductor Package 1

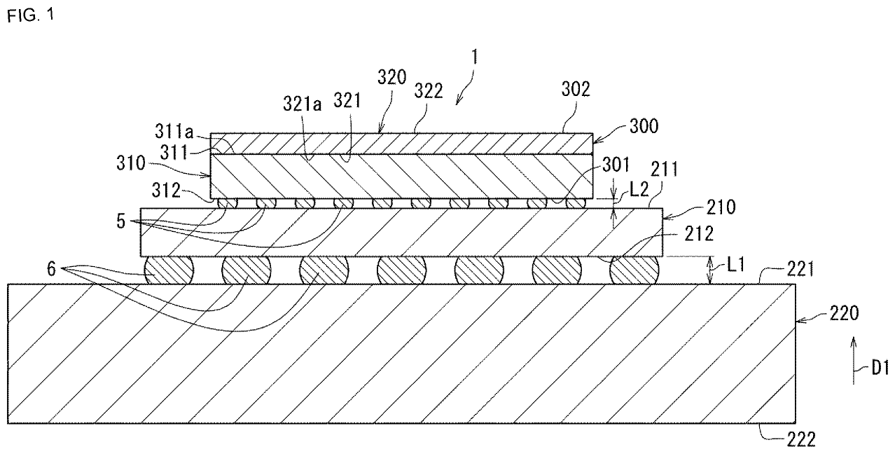

FIG. 1 is a simplified sectional view illustrating a first embodiment of a stacked semiconductor package. As illustrated in FIG. 1, a stacked semiconductor package 1 includes a first substrate 210 and a three-dimensional device 300 stacked in a first direction D1 with respect to the first substrate 210. The first direction D1 is an upward direction in FIG. 1.

The first substrate 210 is an inorganic substrate made of, for example, Si or SiO₂ (so-called silicon interposer substrate or glass interposer substrate), an organic substrate made of flame retardant type 4 (FR4), epoxy, polyimide, or the like (so-called organic package substrate), or the like. Wires are provided inside the first substrate 210 and on the major surface thereof and electrically connected to the three-dimensional device 300. On the major surface of the first substrate 210, conductive members such as external terminals, conductive bumps, conductive pillars, or solders may be provided. Similar conductive members may also be provided on a major surface, which faces the first substrate 210, of the three-dimensional device 300.

The three-dimensional device 300 includes a semiconductor integrated circuit component 310 and a passive component 320 stacked on each other in the first direction D1. The semiconductor integrated circuit component 310 is, for example, an electronic component such as an integrated circuit (IC), a central processing unit (CPU), a power management IC (PMIC), a memory, or a transistor. The passive component 320 is an electronic component such as a resistor, a capacitor, or an inductor and does not include any active element such as a transistor. A passive element of the passive component 320 is a resistive element, a capacitor element, an inductor element, or the like. That is, a passive component includes an element assembly, an internal wire, or the like, and a passive element represents, for example, a coil or the like in a passive component and does not include an element assembly or the like. The stacking order in the first direction D1 of the semiconductor integrated circuit component 310 and the passive component 320 may be optionally determined.

A first major surface 211, which faces the three-dimensional device 300, of the first substrate 210 and a first major surface 301, which faces the first substrate 210, of the three-dimensional device 300 with first connection members 5 interposed therebetween while being separated from each other. The first connection member 5 is, for example, a solder, a conductor bump, or a conductor pillar. The plurality of first connection members 5 are provided. It is only necessary that at least some of the plurality of first connection members 5 are conductive, and some of the plurality of first connection members 5 may be insulating.

A first major surface 311, which faces the passive component 320, of the semiconductor integrated circuit component 310 includes a flat surface 311a. A first major surface 321, which faces the semiconductor integrated circuit, of the passive component 320 includes a flat surface 321a. The flat surfaces 311a and 321a are each a surface that is flat. The flat surface 311a of the semiconductor integrated circuit component 310 and the flat surface 321a of the passive component 320 are bonded together while being in contact with each other.

With the configuration described above, since the flat surface 311a of the semiconductor integrated circuit component 310 and the flat surface 321a of the passive component 320 are bonded together while being in contact with each other, the thickness of the three-dimensional device 300 can be reduced so that a reduction in the thickness of the stacked semiconductor package 1 can be achieved. Further, with the passive component 320, noise reduction and power control can be more easily performed.

Herein, “‘flat’ of the flat surface 311a of the semiconductor integrated circuit component 310” indicates a state in which the surface roughness of the flat surface 311a is smaller than either 1/1000 of the thickness of the semiconductor integrated circuit component 310 or 10 nm. “‘Flat’ of the flat surface 321a of the passive component 320” indicates a state in which the surface roughness of the flat surface 321a is smaller than either 1/1000 of the thickness of the passive component 320 or 10 nm. The thickness of each member refers to the size in the first direction D1 of each member.

“Surface roughness” is an arithmetic average height (Sa). “flat” refers to a state in which Sa is, for example, 0.2 nm. An atomic force microscope (AFM) is used to measure Sa. Surface roughness is the average value of Sa at five points on the surface of a component. When the flat surfaces 311a and 321a can be isolated from each other, this method can be used. When the flat surfaces 311a and 321a cannot be isolated from each other, however, the surface roughness may be calculated from a cross section of the three-dimensional device. To be specific, a cross section of the bonded portion of the flat surfaces 311a and 321a is exposed by a known method such as ion milling, and an image of the bonded portion is acquired by a transmission electron microscope (TEM) or the like. The magnification at this time is preferably 300 K or more. The interface between the flat surfaces 311a and 321a can be recognized from differences in grain boundaries or the like. A straight line (drawn by the least squares method) is drawn at the position corresponding to the interface by using the acquired image. Arithmetic average roughness (Ra) is measured with respect to this straight line, and the surface roughness can be determined.

Further, “bonding between the flat surfaces 311a and 321a” refers to room temperature direct bonding by atomic diffusion or ion coupling, hybrid bonding with heat application, or the like. Further, “bonding” may indicate a chemical coupling state such as covalent coupling, ionic coupling, or metallic coupling, and may indicate a mechanical strength coupling state. As a method of measuring bonding strength, there is a method including, for example, bonding the flat surface of a passive component to the flat surface of a semiconductor integrated circuit component, fixing the flat surfaces of the semiconductor integrated circuit component and the passive component to each other, applying a force vertical to the bonded flat surfaces by a bond tester, for example, and measuring the bonding strength. Alternatively, a pressing tool may be provided above the bonded flat surfaces and the bonding strength may be measured with lateral pressing. Surfaces with a bonding strength of 1 N or more are regarded as being in close contact with each other. Surfaces with a bonding strength of 1 N or more are not to be peeled off by vibration or handling, such as lateral pressing with tweezers for example. Further, bonding strength may be determined from a breakdown mode rather than a fixing force. If there occurs a breakdown in a portion other than bonded flat surfaces, which is commonly known as “bulk breakdown”, it can be said that the bonding strength is sufficiently high.

Further, “the first major surface 211 of the first substrate 210 and the first major surface 301 of the three-dimensional device 300 are separated from each other” indicates that the first major surface 211 of the first substrate 210 and the first major surface 301 of the three-dimensional device 300 are separated from each other while being parallel to each other. “Surfaces are parallel to each other” includes that surfaces are parallel to each other within the range of general manufacturing variations. To be specific, the angle between the first major surface 211 of the first substrate 210 and the first major surface 301 of the three-dimensional device 300 is 10° or less. Further, when both the first major surface 211 of the first substrate 210 and the first major surface 301 of the three-dimensional device 300 are warped, the distance between the first major surface 211 and the first major surface 301 (corresponding to a second distance L2 of FIG. 1) is determined by using surfaces obtained by the least squares method. The second distance L2 represents the average distance between the first major surface 211 of the first substrate 210 and the first major surface 301 of the three-dimensional device 300 at a specific cross section obtained by performing cross-section polishing or the like on the stacked semiconductor package 1. The distance between the first major surface 211 and the first major surface 301 is, for example, 20 μm. Note that, the gap between the first major surface 211 and the first major surface 301 may be filled with an underfill, a mold resin material, or the like.

Method of Manufacturing Stacked Semiconductor Package 1

Next, a method of manufacturing the stacked semiconductor package 1 is described.

As illustrated in FIG. 1, the first major surface 311 of the semiconductor integrated circuit component 310 is polished to provide the flat surface 311a. Further, the first major surface 321 of the passive component 320 is polished to provide the flat surface 321a. After that, the flat surface 311a of the semiconductor integrated circuit component 310 and the flat surface 321a of the passive component 320 are bonded together while being in contact with each other to form the three-dimensional device 300. After that, the first major surface 301 of the three-dimensional device 300 and the first major surface 211 of the first substrate 210 are connected to each other with the first connection members 5 interposed therebetween while being separated from each other.

With this, since the flat surface 311a of the semiconductor integrated circuit component 310 and the flat surface 321a of the passive component 320 are bonded together while being in contact with each other, the thickness of the three-dimensional device 300 can be reduced so that a reduction in the thickness of the stacked semiconductor package 1 can be achieved.

Note that, a semiconductor substrate including a plurality of semiconductor integrated circuit components, and a passive substrate including a plurality of passive components may be prepared, the semiconductor substrate may be bonded to the passive substrate, and then the resultant may be singulated into sets of the semiconductor integrated circuit components and the passive components, to thereby form a plurality of stacked semiconductor packages. Alternatively, one of a semiconductor substrate and a passive substrate may be singulated by component, the components obtained by singulation may be bonded to the other of the semiconductor substrate and the passive substrate, and then the other substrate may be singulated by component, to thereby form a plurality of stacked semiconductor packages.

2. Preferred Mode

Configuration of Stacked Semiconductor Package 1

As illustrated in FIG. 1, the first substrate 210 has a second major surface 212 on the opposite side of the first major surface 211. The three-dimensional device 300 has a second major surface 302 on the opposite side of the first major surface 301. The semiconductor integrated circuit component 310 has a second major surface 312 on the opposite side of the first major surface 311. The passive component 320 has a second major surface 322 on the opposite side of the first major surface 321.

The first major surface 301 of the three-dimensional device 300 is coincident with the second major surface 312 of the semiconductor integrated circuit component 310. The second major surface 302 of the three-dimensional device 300 is coincident with the second major surface 322 of the passive component 320. The passive component 320 is stacked in the first direction D1 with respect to the semiconductor integrated circuit component 310.

The semiconductor integrated circuit component 310 is electrically connected to the passive component 320 via the flat surfaces 311a and 321a. With this, the flat surfaces 311a and 321a can achieve both mechanical connection and electrical connection. Note that, the semiconductor integrated circuit component 310 is not necessarily electrically connected to the passive component 320, and the degree of freedom in circuit design can be improved.

It is preferred that the area of the flat surface 311a of the semiconductor integrated circuit component 310 is larger than half of the area of the first major surface 311 of the semiconductor integrated circuit component 310, and the area of the flat surface 321a of the passive component 320 is larger than half of the area of the first major surface 321 of the passive component 320. With this, with the flat surfaces having large areas, unnecessary unevenness can be reduced so that the thickness of the three-dimensional device 300 can be more reduced.

It is only necessary that at least a part of the first major surface 311 is the flat surface 311a. However, since the adhesion between the components 310 and 320 is low when the area of the flat surface 311a is small, the flat surface 311a preferably covers half or more of the area of the first major surface 311. Similarly, it is only necessary that at least a part of the first major surface 321 is the flat surface 321a, and the flat surface 321a preferably covers half or more of the area of the first major surface 321.

The positions of the facing flat surfaces 311a and 321a may be offset from each other within a general permissible range in a manufacturing process. For example, when wires exposed on the respective flat surfaces are brought into contact with each other, an offset between the flat surfaces 311a and 321a with which contact areas of the wires with the flat surfaces 311a and 321a without any offset, which are references, are not decreased by more than 50% is regarded as being within the permissible range in the manufacturing process.

It is preferred that the flat surface 311a of the semiconductor integrated circuit component 310 and the flat surface 321a of the passive component 320 each are made of an inorganic substance. Examples of the inorganic substance include Cu, Al, Au, Ti, Ta, Si, Ge, GaN, GaP, GaAs, InP, SiN, TiN, and SiO₂. With this, as compared to a case where the flat surfaces 311a and 321a are made of organic substances, the flat surfaces 311a and 321a are easily flattened. Further, the hardness of each of the flat surfaces 311a and 321a is high and the strength of the three-dimensional device 300 can thus be high.

The respective flat surfaces 311a and 321a may be made of the same or different inorganic materials. Further, an inorganic material for a portion of the same flat surface 311a or 321a may be different from an inorganic material for another portion of the same flat surface 311a or 321a. For example, on the flat surface 321a of the passive component 320, a portion of the flat surface 321a may include the surface of the extended wire of a passive element and another portion of the flat surface 321a may include the surface of an insulating layer containing Si.

It is only necessary that at least the flat surface 311a of the semiconductor integrated circuit component 310 is made of an inorganic substance, and the remaining portion of the semiconductor integrated circuit component 310 may be made of an organic substance. Similarly, it is only necessary that at least the flat surface 321a of the passive component 320 is made of an inorganic substance, and the remaining portion of the passive component 320 may be made of an organic substance.

As illustrated in FIG. 1, the stacked semiconductor package 1 further includes a second substrate 220. The first substrate 210 is stacked in the first direction D1 with respect to the second substrate 220. The second major surface 212, which faces the second substrate 220, of the first substrate 210 and a first major surface 221, which faces the first substrate 210, of the second substrate 220 are separated from each other and connected to each other with second connection members 6 interposed therebetween. The second connection member 6 is a material like the first connection member 5.

A first distance L1 between the second major surface 212 of the first substrate 210 and the first major surface 221 of the second substrate 220 is larger than the second distance L2 between the first major surface 211 of the first substrate 210 and the first major surface 301 of the three-dimensional device 300. With this, the circuit system can be increased in size so that the degree of freedom in circuit design can be improved.

“The second major surface 212 of the first substrate 210 is separated from the first major surface 221 of the second substrate 220” indicates that the second major surface 212 of the first substrate 210 and the first major surface 221 of the second substrate 220 are separated from each other while being parallel to each other. “Surfaces are parallel to each other” includes that surfaces are parallel to each other within the range of general manufacturing variations. To be specific, the angle between the second major surface 212 of the first substrate 210 and the first major surface 221 of the second substrate 220 is 10° or less. Further, when both the second major surface 212 of the first substrate 210 and the first major surface 221 of the second substrate 220 are warped, the first distance L1 between the second major surface 212 and the first major surface 221 is determined by using surfaces obtained by the least squares method. The first distance L1 represents the average distance between the second major surface 212 of the first substrate 210 and the first major surface 221 of the second substrate 220 at a specific cross section obtained by performing cross-section polishing or the like on the stacked semiconductor package 1. The first distance L1 is, for example, 300 μm. Note that, the gap between the second major surface 212 and the first major surface 221 may be filled with an underfill, a mold resin material, or the like.

The design accuracy of the second substrate 220 is lower (poorer) than that of the first substrate 210. In other words, the second connection member 6 provided on the second substrate 220 is larger than the first connection member 5 provided on the first substrate 210. Thus, the height of the second connection member 6 connected between the second substrate 220 and the first substrate 210 is larger than the height of the first connection member 5 connected between the first substrate 210 and the three-dimensional device 300. That is, the first distance L1 is larger than the second distance L2. In this way, the design accuracy difference between the first substrate 210 and the second substrate 220 is related to the size difference between the connection members 5 and 6, that is, the length difference between the first distance L1 and the second distance L2. High design accuracy leads to a small distance, and poor design accuracy leads to a large distance.

Method of Manufacturing Stacked Semiconductor Package 1

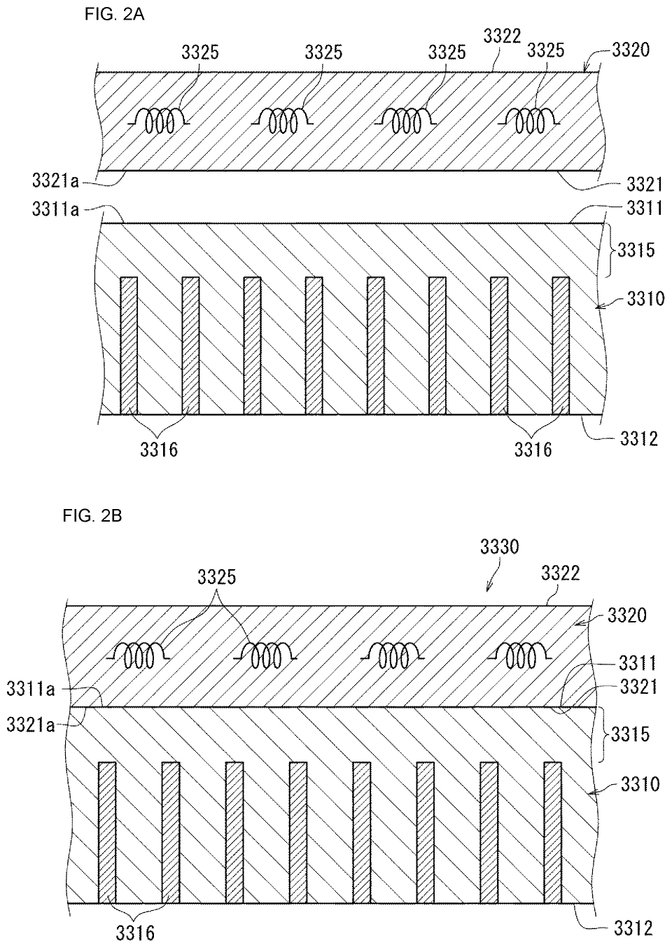

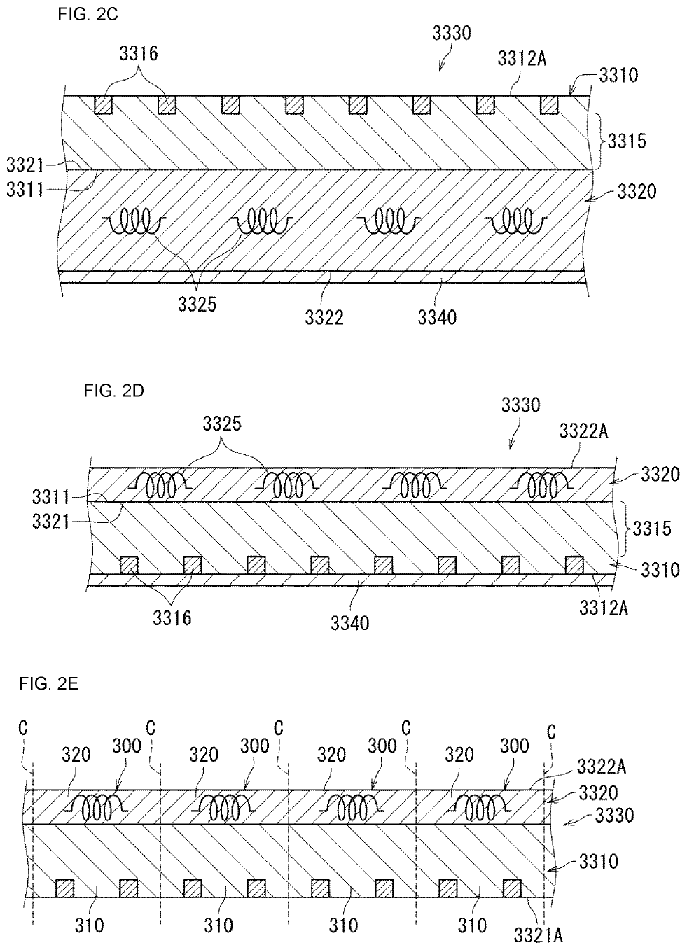

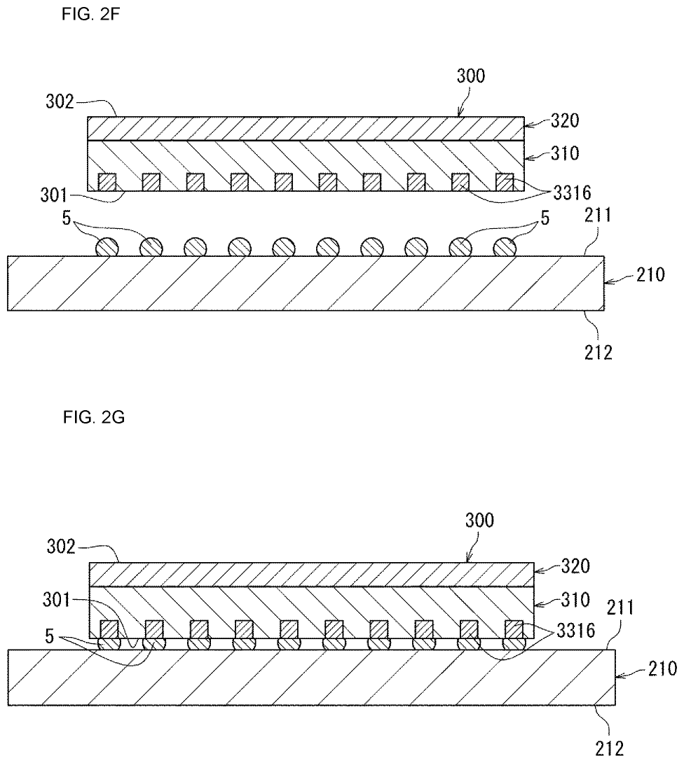

Next, with reference to FIG. 2A to FIG. 2G, a method of manufacturing the stacked semiconductor package 1 is described. In FIG. 2A to FIG. 2E, as a matter of convenience, the aspect ratio (height-to-width ratio) of the three-dimensional device is changed from FIG. 2F and FIG. 2G. In FIG. 2A to FIG. 2E, as a matter of convenience, the number of wires 3316 is changed from FIG. 2F.

As illustrated in FIG. 2A, a semiconductor substrate 3310 including a plurality of semiconductor integrated circuit components, and a passive substrate 3320 including a plurality of passive components are prepared. The semiconductor substrate 3310 includes a device layer including a semiconductor element region, namely, an active layer 3315 and the plurality of wires 3316 for extracting a signal from the active layer 3315 or supplying power. The wire 3316 may be a wire that extends in the substrate thickness direction on the basis of a known art, such as a through-Si via (TSV), as in FIG. 2A, or may be a wire that is stacked on the semiconductor substrate surface, such as a back-end-of-line (BEOL) wire. The passive substrate 3320 includes a plurality of passive elements 3325. In FIG. 2A, the passive element 3325 is an inductor element. The semiconductor substrate 3310 has a first major surface 3311 and a second major surface 3312 located on opposite sides of each other. The passive substrate 3320 has a first major surface 3321 and a second major surface 3322 located on opposite sides of each other. The first major surface 3311 of the semiconductor substrate 3310 is polished to provide a flat surface 3311a. Further, the first major surface 3321 of the passive substrate 3320 is polished to provide a flat surface 3321a. In the present example, chemical mechanical polisher (CMP) polishing is used.

As illustrated in FIG. 2B, the flat surface 3311a of the semiconductor substrate 3310 and the flat surface 3321a of the passive substrate 3320 are bonded together while being in contact with each other to form a multilayer body 3330. As illustrated in FIG. 2C, a tape 3340 is applied to the second major surface 3322 of the passive substrate 3320, and the multilayer body 3330 is fixed to a base, which is not illustrated, with the tape 3340. The second major surface 3312 (see FIG. 2B) side of the semiconductor substrate 3310 is polished to form a new second major surface 3312A. On the second major surface 3312A of the semiconductor substrate 3310, external terminals, which are not illustrated, are formed to be connected to the wires 3316. After that, the tape 3340 is removed from the second major surface 3322 of the passive substrate 3320.

As illustrated in FIG. 2D, the tape 3340 is applied to the second major surface 3312A of the semiconductor substrate 3310, and the multilayer body 3330 is fixed to a base, which is not illustrated, with the tape 3340. The second major surface 3322 (see FIG. 2C) side of the passive substrate 3320 is ground to form a new second major surface 3322A. After that, the tape 3340 is removed from the second major surface 3312A of the semiconductor substrate 3310.

As illustrated in FIG. 2E, the multilayer body 3330 is singulated along cut lines C into individual sets of the semiconductor integrated circuit components 310 and the passive components 320, thereby forming the plurality of three-dimensional devices 300 each including a set of the semiconductor integrated circuit component 310 and the passive component 320.

As illustrated in FIG. 2F, the first substrate 210 is prepared, and the first connection members 5 are provided on the first major surface 211 of the first substrate 210. After that, as illustrated in FIG. 2G, the first major surface 301 of the three-dimensional device 300 and the first major surface 211 of the first substrate 210 are connected to each other with the first connection members 5 interposed therebetween while being separated from each other. The first major surface 301 of the three-dimensional device 300 corresponds to the second major surface 3312A of the semiconductor substrate 3310, and the second major surface 302 of the three-dimensional device 300 corresponds to the second major surface 3322A of the passive substrate 3320. The wires 3316 of the semiconductor integrated circuit component 310 are connected to the first connection members 5.

After that, as illustrated in FIG. 1, the second substrate 220 is prepared, the connection members 6 are provided on the first major surface 221 of the second substrate 220, and the second major surface 212 of the first substrate 210 and the first major surface 221 of the second substrate 220 are connected to each other with the connection members 6 interposed therebetween while being separated from each other. With this, the stacked semiconductor package 1 is manufactured.

Modification of Method of Manufacturing Stacked Semiconductor Package 1

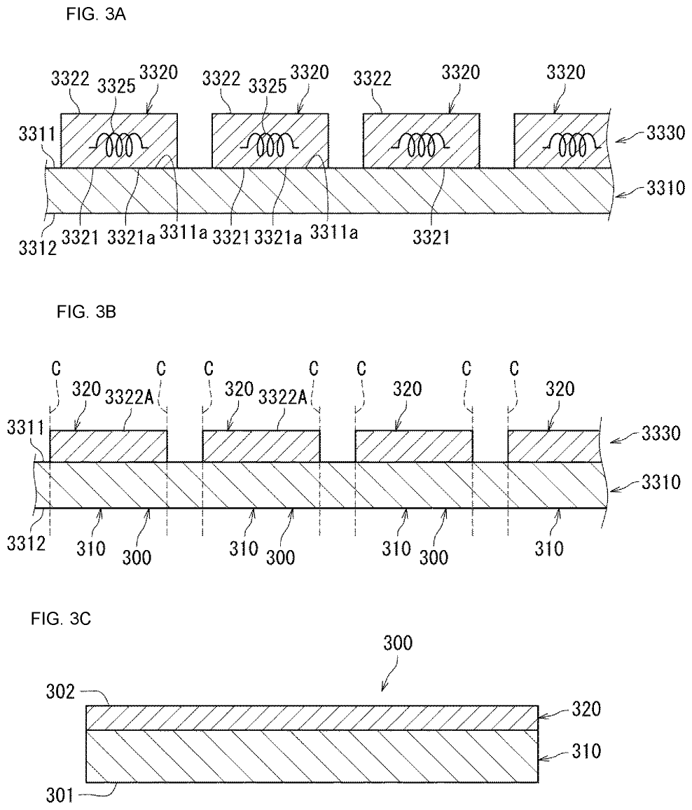

Next, with reference to FIG. 3A to FIG. 3C, a modification of a method of manufacturing the stacked semiconductor package 1 is described. In FIG. 3A and FIG. 3B, as a matter of convenience, the aspect ratio (height-to-width ratio) of the three-dimensional device is changed from FIG. 3C.

As illustrated in FIG. 3A, the semiconductor substrate 3310 including a plurality of semiconductor integrated circuit components, and the plurality of passive substrates 3320 including passive components are prepared. The semiconductor substrate 3310 includes an active layer and a plurality of wires as described above. The passive substrate 3320 includes the passive element 3325. The semiconductor substrate 3310 has the first major surface 3311 and the second major surface 3312 located on opposite sides of each other. The passive substrate 3320 has the first major surface 3321 and the second major surface 3322 located on opposite sides of each other. The first major surface 3311 of the semiconductor substrate 3310 is polished to provide the flat surface 3311a. Further, the first major surface 3321 of the passive substrate 3320 is polished to provide the flat surface 3321a. After that, the flat surface 3311a of the semiconductor substrate 3310 and the flat surfaces 3321a of the passive substrates 3320 are bonded together while being in contact with each other to form the multilayer body 3330.

After that, the second major surface 3322 side of the passive substrate 3320 is ground to form the new second major surface 3322A of the passive substrate 3320, as illustrated in FIG. 3B. After that, the multilayer body 3330 is singulated along the cut lines C into individual sets of the semiconductor integrated circuit components 310 and the passive components 320 to form the plurality of three-dimensional devices 300 each including a set of the semiconductor integrated circuit component 310 and the passive component 320. As illustrated in FIG. 3C, the first major surface 301 of the three-dimensional device 300 corresponds to the second major surface 3312 of the semiconductor substrate 3310, and the second major surface 302 of the three-dimensional device 300 corresponds to the second major surface 3322A of the passive substrate 3320.

After that, as illustrated in FIG. 1, the first major surface 301 of the three-dimensional device 300 and the first major surface 211 of the first substrate 210 are connected to each other with the first connection members 5 interposed therebetween while being separated from each other. Then, the second major surface 212 of the first substrate 210 and the first major surface 221 of the second substrate 220 are connected to each other with the connection members 6 interposed therebetween while being separated from each other. With this, the stacked semiconductor package 1 is manufactured.

3. Preferred Mode of Passive Component

Schematic Configuration of Inductor Component 3

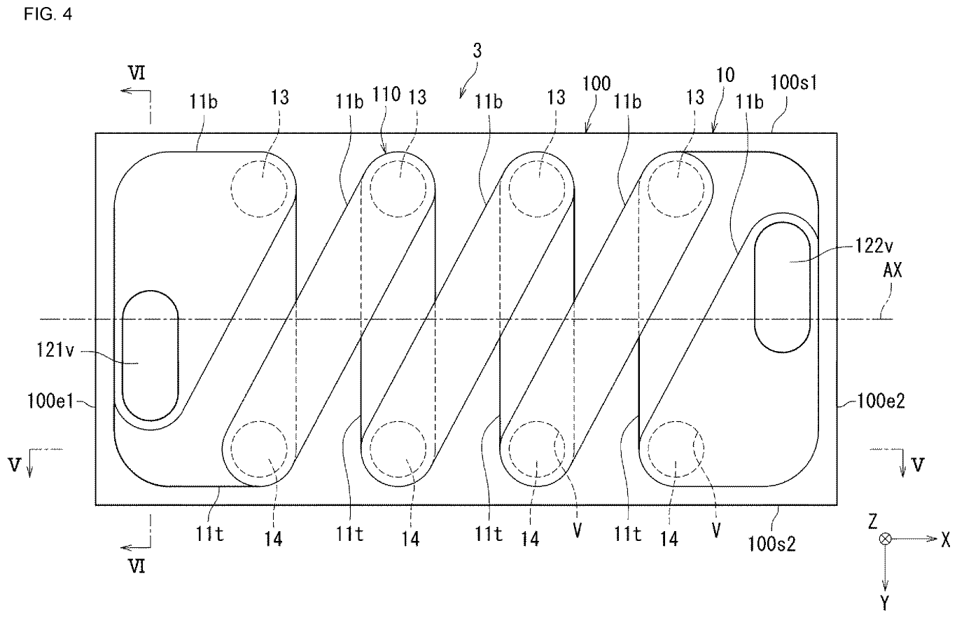

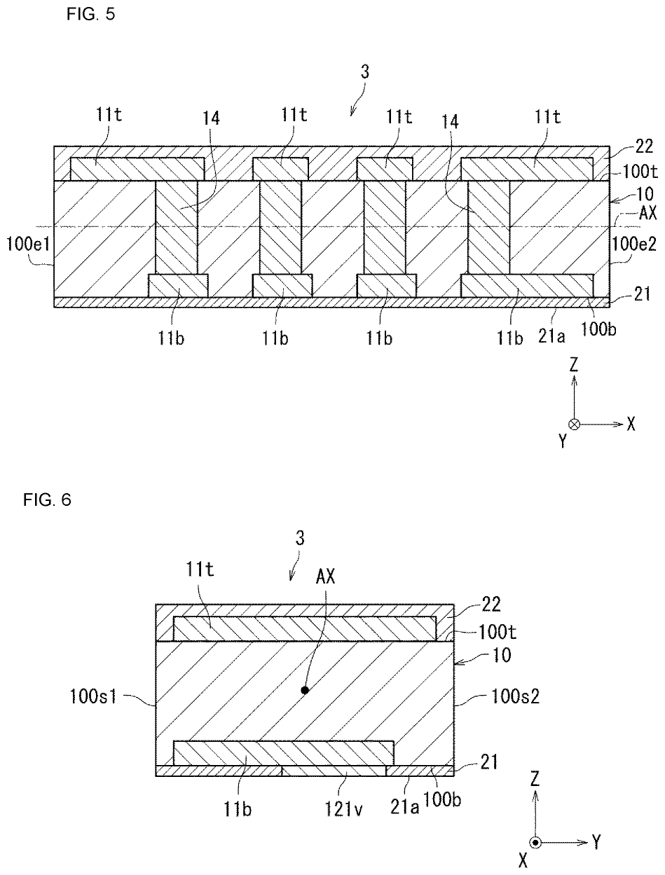

The passive component 320 is preferably an inductor component 3. FIG. 4 is a schematic bottom view of the inductor component 3 when viewed from the bottom surface side. FIG. 5 is a sectional view taken along the line V-V of FIG. 4. FIG. 6 is a sectional view taken along the line VI-VI of FIG. 4. Note that, as a matter of convenience, an element assembly 10 is illustrated transparently in FIG. 4 to facilitate the understanding of the structure, but the element assembly 10 may be semi-transparent or opaque. Further, the illustrations of an insulator and an inorganic layer are omitted in FIG. 4.

The inductor component 3 is, for example, a surface mount inductor component that is used for a high-frequency signal transmission circuit. As illustrated in FIG. 4, FIG. 5, and FIG. 6, the inductor component 3 includes the element assembly 10, a coil 110 provided to the element assembly 10 and wound spirally along an axis AX, an inorganic layer 21 provided on a first major surface (bottom surface 100b) of the element assembly 10, and an insulator 22 provided on a second major surface (top surface 100t) of the element assembly 10. A bottom surface 21a of the inorganic layer 21 corresponds to the flat surface 321a of the first major surface 321 of the passive component 320.

The element assembly 10 has its length, width, and height. The element assembly 10 has a first end surface 100e1 and a second end surface 100e2 located on the respective end sides in the length direction, a first side surface 100s1 and a second side surface 100s2 located on the respective end sides in the width direction, and a bottom surface 100b and a top surface 100t located on the respective end sides in the height direction. That is, an outer surface 100 of the element assembly 10 includes the first end surface 100e1, the second end surface 100e2, the first side surface 100s1, the second side surface 100s2, the bottom surface 100b, and the top surface 100t.

Note that, as illustrated in FIG. 4, FIG. 5, and FIG. 6, in the following, as a matter of convenience of description, the length direction (longitudinal direction) of the element assembly 10 that is the direction from the first end surface 100e1 to the second end surface 100e2 is referred to as “X direction”. Further, the width direction of the element assembly that is the direction from the first side surface 100s1 to the second side surface 100s2 is referred to as “Y direction”. Further, the height direction of the element assembly 10 that is the direction from the bottom surface 100b to the top surface 100t is referred to as “Z direction”. The X direction, the Y direction, and the Z direction are directions orthogonal to each other, and a right-handed system is formed with X, Y, and Z arranged in this order.

Herein, “the outer surface 100 of the element assembly 10”, which includes the first end surface 100e1, the second end surface 100e2, the first side surface 100s1, the second side surface 100s2, the bottom surface 100b, and the top surface 100t of the element assembly 10, does not simply mean a surface that faces the outer peripheral side of the element assembly 10 but means a surface that defines the boundary between the outside and inside of the element assembly 10. Further, “above the outer surface 100 of the element assembly 10” does not indicate an absolute direction such as a vertically upward direction defined by the direction of gravity, but indicates a direction to the outside, which is defined by the outer surface 100 that is the boundary between the outside and the inside, with respect to the outer surface 100. Thus, “above the outer surface 100” is a relative direction defined by the orientation of the outer surface 100. Further, “above” a certain element includes not only an upper position separated from the element, that is, an upper position with the interposition of another object on the element or a spaced-apart upper position, but also a position directly on the element in contact therewith.

The axis AX of the coil 110 is placed parallel to the bottom surface 100b. The coil 110 includes a plurality of first coil wires (bottom surface wires 11b), a plurality of second coil wires (top surface wires 11t), a plurality of first through wires 13, and a plurality of second through wires 14. The bottom surface wires 11b are provided on the bottom surface 100b side with respect to the axis AX and arranged along the axis AX on a plane parallel to the bottom surface 100b. The top surface wires 11t are provided on the top surface 100t side with respect to the axis AX and arranged along the axis AX on a plane parallel to the top surface 100t. The first through wires 13 extend from the bottom surface wires 11b to the top surface wires 11t and are arranged along the axis AX. The second through wires 14 extend from the bottom surface wires 11b to the top surface wires 11t and are provided on the opposite side of the first through wires 13 with respect to the axis AX and arranged along the axis AX. The bottom surface wires 11b, the first through wires 13, the top surface wires 11t, and the second through wires 14 are connected in this order to form at least a part of the spiral.

The axis AX refers to the intersection line between a first plane passing through the center between the bottom surface wire 11b and the top surface wire 11t, and a second plane passing through the center between the first through wire 13 and the second through wire 14. That is, the axis AX is a straight line passing through the center of the inner diameter portion of the coil 110. The axis AX of the coil 110 does not have dimensions in the direction orthogonal to the axis AX.

Inductor Component 3

The volume of the inductor component 3 is 0.08 mm³ or less, and the length of the long side of the inductor component 3 is 0.65 mm or less. The length of the long side of the inductor component 3 refers to the largest one of the length, width, and height values of the inductor component 3 and refers to the length in the X direction in this embodiment. With the configuration described above, since the volume of the inductor component 3 is small and the long side of the inductor component 3 is short, the weight of the inductor component 3 is small. Thus, even with small outer electrodes 121 and 122, the required mounting strength can be obtained. Further, the thickness of the inductor component 3 is preferably 200 μm or less. With this, the inductor component 3 can be reduced in thickness.

To be specific, the size (length (X direction)×width (Y direction)×height (Z direction)) of the inductor component 3 is 0.6 mm×0.3 mm×0.3 mm, 0.4 mm×0.2 mm×0.2 mm, 0.25 mm×0.125 mmx 0.120 mm, or the like. Further, the width is not necessarily equal to the height, and the size of the inductor component 3 may be, for example, 0.4 mm×0.2 mm×0.3 mm.

Element Assembly 10

The element assembly 10 is made of an insulating resin. As the insulating resin, for example, a photosensitive permanent film (permanent photoresist) or an inorganic filler-containing insulating resin is used. A photosensitive permanent film is a photoresist that is not removed after processing.

Note that, the element assembly 10 may include, for example, a glass sintered body or a glass substrate. The glass substrate may be a single-layer glass substrate. With the element assembly a large portion of which is made of glass, losses such as eddy current losses at high frequencies can be prevented.

Coil 110

The coil 110 includes the plurality of bottom surface wires 11b, the plurality of top surface wires 11t, the plurality of first through wires 13, and the plurality of second through wires 14. The bottom surface wires 11b, the first through wires 13, the top surface wires 11t, and the second through wires 14 are sequentially connected to form at least a part of the coil 110 wound in the axis AX direction.

With the configuration described above, since the coil 110 is the coil 110 having a so-called helical shape, in a cross section orthogonal to the axis AX, the region in which the bottom surface wires 11b, the top surface wires 11t, the first through wires 13, and the second through wires 14 run parallel to each other along the winding direction of the coil 110 can be reduced so that stray capacitance in the coil 110 can be reduced.

Here, a helical shape refers to the shape of a coil that has more than one turn in total and has less than one turn in a cross section orthogonal to the axis. more than one turn refers to a state in which a coil has, in a cross section orthogonal to the axis, a portion in which the wires are located side-by-side in the radial direction when viewed from the axial direction and run parallel to each other in the winding direction. Less than one turn refers to a state in which a coil does not have, in a cross section orthogonal to the axis, a portion in which the wires are located side-by-side in the radial direction when viewed from the axial direction and run parallel to each other in the winding direction.

The bottom surface wire 11b is slightly inclined to the X direction and extends in the Y direction. The bottom surface wire 11b is embedded in the element assembly 10 so as to be exposed from the bottom surface 100b. The plurality of bottom surface wires 11b are placed parallel to each other along the X direction. When viewed from the direction orthogonal to the bottom surface 100b, the bottom surface wires 11b at the respective ends in the axis AX direction are formed into a triangular shape, while the remaining bottom surface wires 11b are formed into a linear shape.

The top surface wire 11t has a shape that extends in the Y direction. The top surface wire 11t is provided on the top surface 100t. The plurality of top surface wires 11t are placed parallel to each other along the X direction. When viewed from the direction orthogonal to the bottom surface 100b, the top surface wires 11t at the respective ends in the axis AX direction are formed into a rectangular shape, while the remaining top surface wires 11t are formed into a linear shape.

The bottom surface wire 11b and the top surface wire 11t are made of good conductor materials such as copper, silver, or gold, or an alloy thereof. The bottom surface wire 11b and the top surface wire 11t may each be a metal film formed by plating, vapor deposition, sputtering, or the like, or may each be a metal sintered body obtained by applying and sintering a conductive paste. Further, the bottom surface wire 11b and the top surface wire 11t may each have a multilayer structure in which a plurality of metal layers are stacked. The thicknesses of the bottom surface wire 11b and the top surface wire 11t are preferably 5 μm or more and 50 μm or less (i.e., from 5 μm to 50 μm).

The first through wire 13 is placed on the first side surface 100s1 side with respect to the axis AX in a through hole V of the element assembly 10, and the second through wire 14 is placed on the second side surface 100s2 side with respect to the axis AX in the through hole V of the element assembly 10. The first through wire 13 and the second through wire 14 each extend in the direction orthogonal to the bottom surface 100b and the top surface 100t. With this, the lengths of the first through wire 13 and the second through wire 14 can be reduced so that the DC resistance (Rdc) can be reduced. All the first through wires 13 and all the second through wires 14 are placed parallel to each other along the X direction. The first through wire 13 and the second through wire 14 are made of materials similar to those for the bottom surface wire 11b and the top surface wire 11t.

Inorganic Layer 21

The inorganic layer 21 is provided on the bottom surface 100b of the element assembly 10 and covers portions exposed from the bottom surface 100b of the bottom surface wires 11b. With this, the bottom surface wire 11b is protected from an external force to prevent the bottom surface wire 11b from being damaged, leading to improved insulation properties of the bottom surface wire 11b. The inorganic layer 21 is made of an inorganic substance. Examples of the inorganic substance include Cu, Al, Au, Ti, Ta, Si, Ge, GaN, GaP, GaAs, InP, SiN, TiN, and SiO₂. The bottom surface 21a of the inorganic layer 21 corresponds to the flat surface 321a of the first major surface 321 of the passive component 320.

Insulator 22

The insulator 22 is provided on the top surface 100t of the element assembly 10 and covers the top surface wires 11t. With this, the top surface wire 11t is protected from an external force to prevent the top surface wire 11t from being damaged, leading to improved insulation properties of the top surface wire 11t. The insulator 22 is preferably an organic insulator. For example, the insulator 22 may be a resin film made of an epoxy-based resin or a polyimide-based resin, which is easily formed.

First Via Wire 121v and Second Via Wire 122v

The inductor component 3 further includes a first via wire 121v and a second via wire 122v. The first via wire 121v is connected to the first end portion of the coil 110, and the second via wire 122v is connected to the second end portion of the coil 110.

The first via wire 121v is provided on the first end surface 100e1 side with respect to the center in the X direction of the element assembly 10. The second via wire 122v is provided on the second end surface 100e2 side with respect to the center in the X direction of the element assembly 10.

The first via wire 121v is embedded in the inorganic layer 21 and exposed from the bottom surface 21a of the inorganic layer 21. The first via wire 121v is connected to the end portion of the bottom surface wire 11b that is located on the first end surface 100e1 side in the axis AX direction.

The second via wire 122v is embedded in the inorganic layer 21 and exposed from the bottom surface 21a of the inorganic layer 21. The second via wire 122v is connected to the end portion of the bottom surface wire 11b that is located on the second end surface 100e2 side in the axis AX direction.

Method of Manufacturing Inductor Component 3

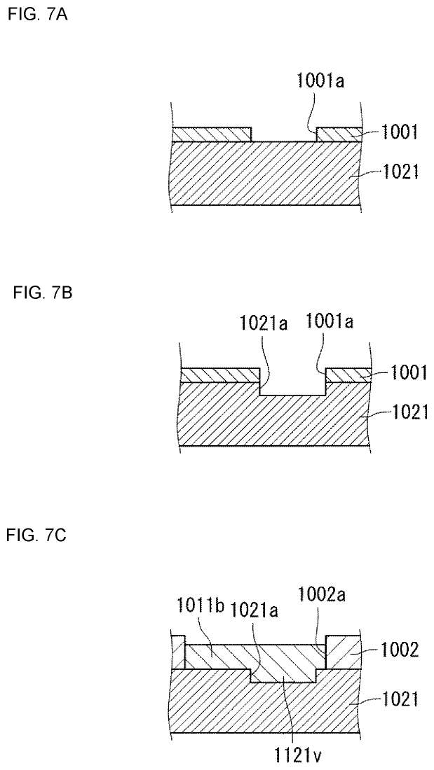

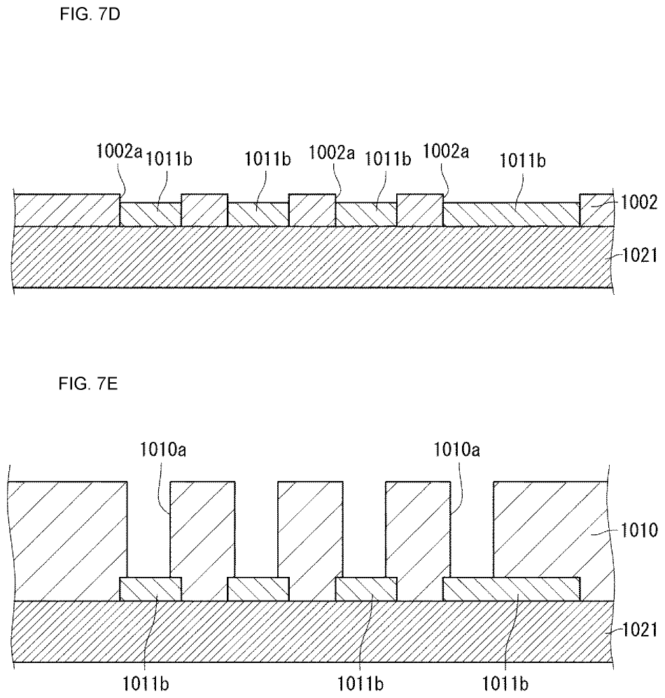

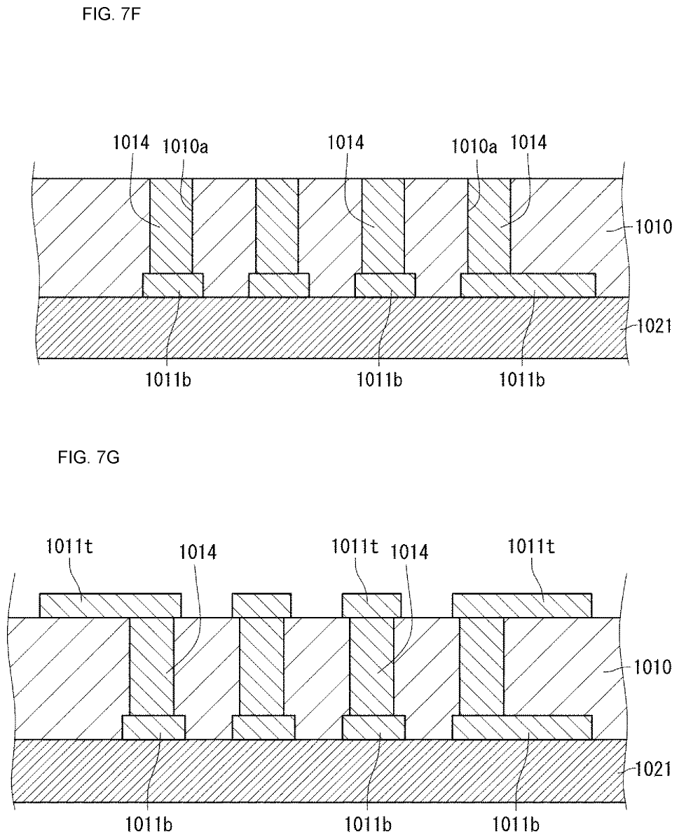

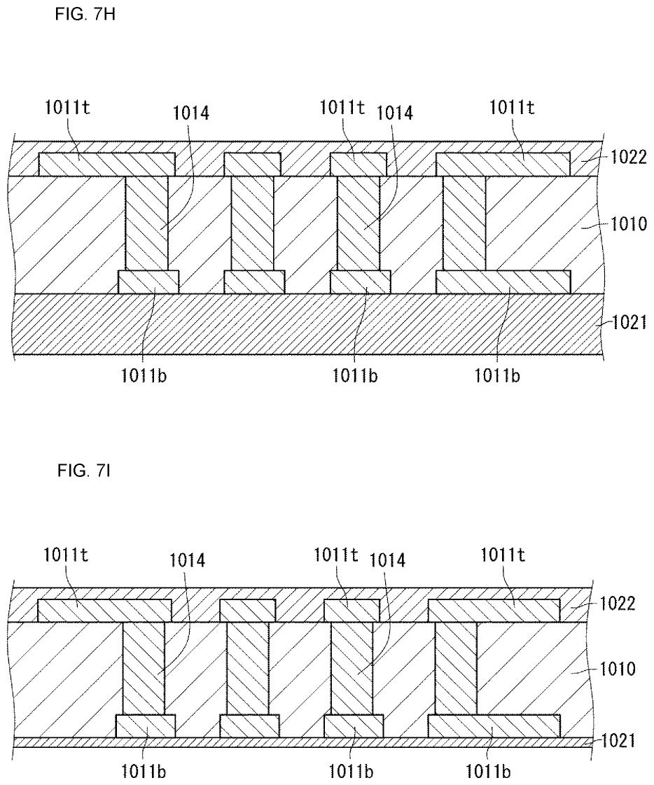

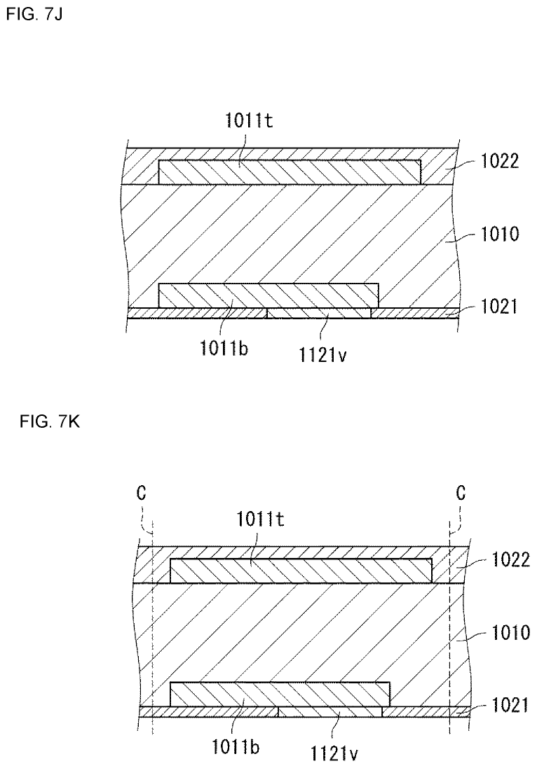

Next, with reference to FIG. 7A to FIG. 7K, a method of manufacturing the inductor component 3 is described. FIG. 7A, FIG. 7B, FIG. 7C, FIG. 7J, and FIG. 7K are drawings corresponding to the cross section taken along the line VI-VI of FIG. 4. FIG. 7D to FIG. 7I are drawings corresponding to the cross section taken along the line V-V of FIG. 4.

As illustrated in FIG. 7A, an inorganic substrate 1021 that corresponds to the inorganic layer 21 is prepared. The inorganic substrate 1021 is, for example, a Si substrate. A first resist layer 1001 is applied onto the upper surface of the inorganic substrate 1021, and a cavity 1001a is formed in a predetermined pattern in the first resist layer 1001 in a photolithography process.

As illustrated in FIG. 7B, the inorganic substrate 1021 is etched through the cavity 1001a to form a groove portion 1021a. Etching may be either dry etching or wet etching. In the present embodiment, plasma etching using a fluorine-based gas is used since a Si substrate is used for the inorganic substrate 1021.

After that, the first resist layer 1001 is removed. As illustrated in FIG. 7C and FIG. 7D, a seed layer, which is not illustrated, is formed on the upper surface of the inorganic substrate 1021, a second resist layer 1002 is applied onto the upper surface of the seed layer, and a cavity 1002a is formed in a predetermined pattern in the second resist layer 1002 in a photolithography process. Then, by electrolytic plating, a bottom surface conductor layer 1011b that corresponds to the bottom surface wire 11b is provided in the cavity 1002a, and a first via conductor layer 1121v that corresponds to the first via wire 121v is provided in the groove portion 1021a. Further, although not illustrated, a second via conductor layer that corresponds to the second via wire 122v is provided like the first via conductor layer 1121v.

In the present embodiment, the semi-additive method is used as the method of forming the bottom surface conductor layer and the via conductor layers, but a known method such as a subtractive method, a full-additive method, or a printing method using a conductive paste may be used. In the present embodiment, Ti/Cu is used for the seed layer, but the type and combination of seeds, such as W, TiW, or Ag, may be selected as needed.

After that, the second resist layer 1002 is removed and the seed layer is etched to provide an insulating resin layer 1010 that corresponds to the element assembly 10 on the upper surface of the inorganic substrate 1021, as illustrated in FIG. 7E. A cavity 1010a is formed in a predetermined pattern in the insulating resin layer 1010 to expose a portion of the bottom conductive layer 1011b from the cavity 1010a in a photolithography process, and the insulating resin layer 1010 is solidified. In the present embodiment, a photosensitive permanent film is used for the insulating resin layer 1010, but, for example, a cavity may be formed in an inorganic filler-containing insulating resin by a laser machining method or a blasting method, or a cavity may be formed by an etching method or the like in an inorganic insulating layer deposited by CVD or the like.

As illustrated in FIG. 7F, a second through conductor layer 1014 that corresponds to the second through wire 14 is formed in the cavity 1010a of the insulating resin layer 1010. Further, although not illustrated, a first through conductor layer that corresponds to the first through wire 13 is provided like the second through conductor layer 1014. To be specific, in the present embodiment, a Ti/Cu seed layer is formed on the upper surface of the insulating resin layer 1010 and the inner surface of the cavity 1010a by using anisotropic sputtering. After that, filled plating is performed and the upper surface of the insulating resin layer 1010 is flattened by CMP, mechanical polishing, or the like. Note that, the through conductor layers may be formed by another forming method including providing a conductive portion in advance on the bottom surface conductor layer and performing electrolytic plating with power supply from the conductive portion.

After that, a seed layer, which is not illustrated, is formed on the upper surface of the insulating resin layer 1010. A resist layer, which is not illustrated, is applied onto the upper surface of the seed layer, and a cavity is formed in a predetermined pattern in the resist layer in a photolithography process. Then, by electrolytic plating, a top surface conductor layer 1011t that corresponds to the top surface wire 11t is provided in the cavity. As illustrated in FIG. 7G, the resist layer is removed and the seed layer is etched.

As illustrated in FIG. 7H, an insulating layer 1022 that corresponds to the insulator 22 is provided on the upper surface of the insulating resin layer 1010 so as to cover the top surface conductor layer 1011t, and the insulating layer 1022 is solidified. The insulating layer 1022 may be a resin that is the same as or different from the resin for the insulating resin layer 1010. Since the insulating layer 1022 is exposed to the outside, as compared to the insulating resin layer 1010, for the insulating layer 1022, a resin with excellent water resistance or a resin with high hardness is preferably used. A resin containing an inorganic filler or the like is more preferably used. This leads to improved insulation properties. Moreover, for the insulating layer 1022, as compared to the insulating resin layer 1010, a highly light-blocking (shielding) resin is preferably used.

As illustrated in FIG. 7I and FIG. 7J, the inorganic substrate 1021 is polished to expose the end surface of the first via conductor layer 1121v and the end surface of the second via conductor layer. The inorganic substrate 1021 is preferably polished by CMP. Note that, the insulating layer 1022 may be polished for thickness adjustment as needed.

As illustrated in FIG. 7K, singulation along the cut lines C is performed. With this, as illustrated in FIG. 6, the inductor component 3 is manufactured.

### 4. Modifications

### First Modification

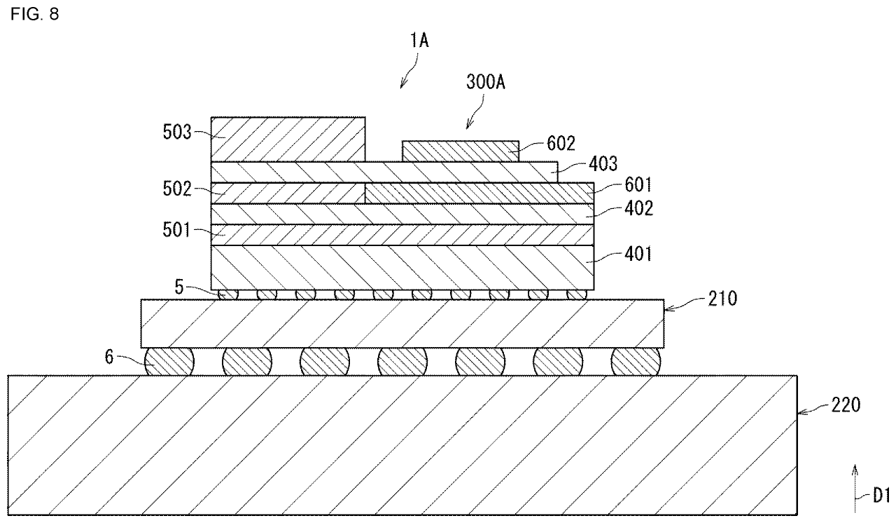

FIG. 8 is a simplified sectional view illustrating a first modification of a stacked semiconductor package. As illustrated in FIG. 8, a stacked semiconductor package 1A of the first modification is different from the stacked semiconductor package 1 of FIG. 1 in the configuration of a three-dimensional device 300A. The remaining configuration is the same as that of the first embodiment, and hence the description thereof is omitted.

As illustrated in FIG. 8, the three-dimensional device 300A includes a plurality of integrated circuit components 401 to 403, a plurality of inductor components 501 to 503, and a plurality of capacitor components 601 and 602. The integrated circuit components 401 to 403 each correspond to an example of “semiconductor integrated circuit component” in the claims and correspond, for example, to an example of the semiconductor integrated circuit component 310 of the first embodiment. The inductor components 501 to 503 and the capacitor components 601 and 602 each correspond to an example of “passive component” in the claims and correspond, for example, to an example of the passive component 320 of the first embodiment.

The plurality of semiconductor integrated circuit components (integrated circuit components 401 to 403) are placed in order in the first direction D1. With this, the degree of freedom in circuit design can be improved. To be specific, the first integrated circuit component 401, the second integrated circuit component 402, and the third integrated circuit component 403 are stacked in sequence in the first direction D1. Note that, the plurality of semiconductor integrated circuit components may be placed in order in the first direction D1 or the direction orthogonal to the first direction D1.

The plurality of passive components (inductor components 501 to 503 and capacitor components 601 and 602) are placed in order in the first direction D1. With this, the degree of freedom in circuit design can be improved. To be specific, the first inductor component 501, the second inductor component 502, and the third inductor component 503 are stacked in sequence in the first direction D1. The first capacitor component 601 and the second capacitor component 602 are stacked in sequence in the first direction D1. The first inductor component 501, the first capacitor component 601, and the second capacitor component 602 are stacked in sequence in the first direction D1.

The first inductor component 501 is located between the first integrated circuit component 401 and the second integrated circuit component 402. The second inductor component 502 and the first capacitor component 601 are located between the second integrated circuit component 402 and the third integrated circuit component 403. The third inductor component 503 and the second capacitor component 602 are stacked on the third integrated circuit component 403.

The plurality of passive components (inductor components 502 and 503 and capacitor components 601 and 602) are placed in order in the direction orthogonal to the first direction D1. With this, the degree of freedom in circuit design can be improved. To be specific, the second inductor component 502 and the first capacitor component 601 are placed in order in the direction orthogonal to the first direction D1. The third inductor component 503 and the second capacitor component 602 are placed in order in the direction orthogonal to the first direction D1. Note that, the plurality of passive components may be placed in order in the first direction D1 or the direction orthogonal to the first direction D1.

Here, bonding between the first integrated circuit component 401 and the first inductor component 501, bonding between the first inductor component 501 and the second integrated circuit component 402, bonding between the second integrated circuit component 402 and the second inductor component 502, bonding between the second integrated circuit component 402 and the first capacitor component 601, bonding between the second inductor component 502 and the third integrated circuit component 403, bonding between the first capacitor component 601 and the third integrated circuit component 403, bonding between the third integrated circuit component 403 and the third inductor component 503, and bonding between the third integrated circuit component 403 and the second capacitor component 602 are each direct bonding using the flat surfaces of the corresponding components as described in the first embodiment.

It is preferred that of all the semiconductor integrated circuit components (integrated circuit components 401 to 403) and all the passive components (inductor components 501 to 503 and capacitor components 601 and 602), a plurality of components are stacked on the same layer, and the respective plurality of components have the same thickness. To be specific, the second inductor component 502 and the first capacitor component 601 are stacked on the same layer, and the second inductor component 502 and the first capacitor component 601 have the same thickness.

With the configuration described above, since the respective plurality of components on the same layer (second inductor component 502 and first capacitor component 601) have the same thickness, even when more components are stacked, the stacked components can be prevented from tilting. Further, since the thicknesses of some components on the same layer are not thicker than necessary, a reduction in the thickness of the stacked semiconductor package 1A can be achieved. Note that, at this time, it is only necessary that the three-dimensional device includes at least one semiconductor integrated circuit component and at least one passive component.

It is preferred that of all the semiconductor integrated circuit components (integrated circuit components 401 to 403) and all the passive components (inductor components 501 to 503 and capacitor components 601 and 602), a plurality of components are stacked on the top layer in the first direction D1, and of the plurality of components on the top layer, at least two components have different thicknesses. To be specific, the third inductor component 503 and the second capacitor component 602 are stacked on the top layer, and the third inductor component 503 and the second capacitor component 602 have different thicknesses.

With the configuration described above, since of the plurality of components on the top layer, the at least two components (third inductor component 503 and second capacitor component 602) have different thicknesses, the components with different thicknesses can be integrated into the top layer. Further, since no component is stacked above the top layer, the process of adjusting the thickness of the top layer is not necessary. Note that, at this time, it is only necessary that the three-dimensional device includes at least one semiconductor integrated circuit component and at least one passive component.

Note that, when a passive component and a semiconductor integrated circuit component exist on the top layer, the thickness of the passive component is preferably larger than the thickness of the semiconductor integrated circuit component. Typically, the active area (the region in which the active layer is formed) of a semiconductor integrated circuit component is a very thin film, and the thicknesses of passive components with low design accuracy are generally thicker. Thus, with a passive component that is thick and thus has an increased volume, the performance can be improved while preventing an increase in the footprint (planar area) of the entire package. Moreover, when a passive component includes an inductor component, the thickness of the inductor component is the largest. Since the energy storage rate of inductor components is generally smaller than that of capacitor components, an inductor component that has an increased thickness and thus has an increased volume contributes to a reduction in the footprint of the entire package. For example, on the top layer, the thickness of a semiconductor integrated circuit component is 100 μm, the thickness of a capacitor component is 220 μm, and the thickness of an inductor component is 330 μm.

It is preferred that of all the semiconductor integrated circuit components (integrated circuit components 401 to 403) and all the passive components (inductor components 501 to 503 and capacitor components 601 and 602), a component closest to the first substrate 210 in the first direction D1 has an area larger than the area of each of the other components. The area of a component refers to an area on a plane vertical to the first direction D1 (plane area). To be specific, the first integrated circuit component 401 closest to the first substrate 210 preferably has an area larger than the area of each of the other components (second and third integrated circuit components 402 and 403, first to third inductor components 501 to 503, and first and second capacitor components 601 and 602).

With the configuration described above, since the area (footprint) of the component closest to the first substrate 210 is the largest, misalignment of other components stacked on the component closest to the first substrate 210 can be absorbed and a wide process margin for cutting the other components can be secured. Note that, at this time, it is only necessary that the three-dimensional device includes at least one semiconductor integrated circuit component and at least one passive component.

Note that, it is more preferred that the areas of the respective semiconductor integrated circuit components and passive components sequentially become smaller along the first direction D1. With this, misalignment of each component can be prevented in the stacking process of each component and a process margin for cutting each component can be secured.

It is preferred that the area of at least one of all the passive components (inductor components 501 to 503 and capacitor components 601 and 602) is smaller than the area of at least one of all the semiconductor integrated circuit components (integrated circuit components 401 to 403). To be specific, the areas of the second inductor component 502 and the third inductor component 503 are smaller than the areas of the respective first to third integrated circuit components 401 to 403. The areas of the first capacitor component 601 and the second capacitor component 602 are smaller than the areas of the respective first to third integrated circuit components 401 to 403.

With the configuration described above, since the passive component having a small area is stacked on the semiconductor integrated circuit component, other functions can be implemented in the empty space of the semiconductor integrated circuit component so that the degree of integration of the three-dimensional device can be improved. Note that, at this time, it is only necessary that the three-dimensional device includes at least one semiconductor integrated circuit component and at least one passive component.

It is preferred that the passive component having a small area described above is a capacitor component. To be specific, the areas of the first capacitor component 601 and the second capacitor component 602 are smaller than the areas of the respective first to third integrated circuit components 401 to 403. With this, the three-dimensional device with a high degree of integration can be provided efficiently. Since capacitor components generally have a higher energy storage rate per unit volume than inductor components, capacitor components are easily miniaturized.

It is preferred that the area of at least one of all the passive components (inductor components 501 to 503 and capacitor components 601 and 602) is larger than the area of at least one of all the semiconductor integrated circuit components (integrated circuit components 401 to 403). To be specific, the area of the first inductor component 501 is larger than the area of the third integrated circuit component 403.

With the configuration described above, since the process nodes (design rules) for the passive components are less strict than those for the semiconductor integrated circuit components, the passive components may be manufactured to have large areas so that the manufacturing cost can be reduced. Note that, at this time, it is only necessary that the three-dimensional device includes at least one semiconductor integrated circuit component and at least one passive component.

It is preferred that the passive component having a large area described above is an inductor component. With this, the three-dimensional device with a high degree of integration can be provided efficiently. The desired circuit constant is obtained by increasing the area of the inductor component.

### Second Modification

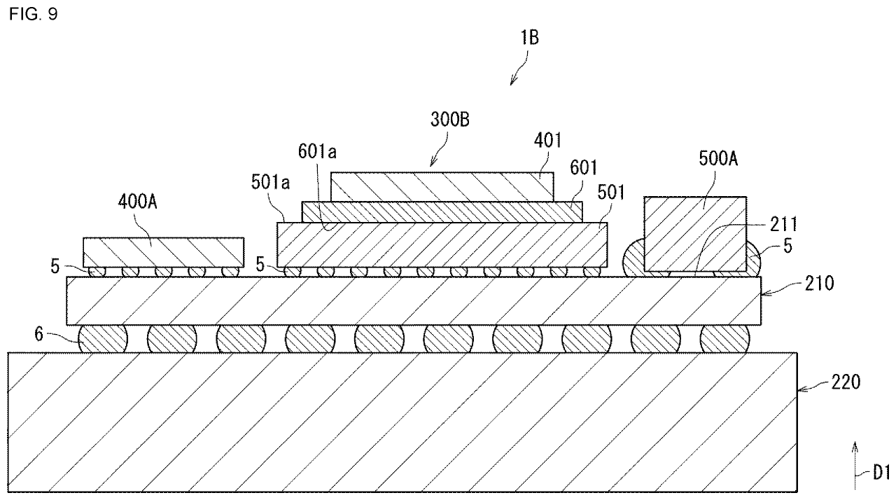

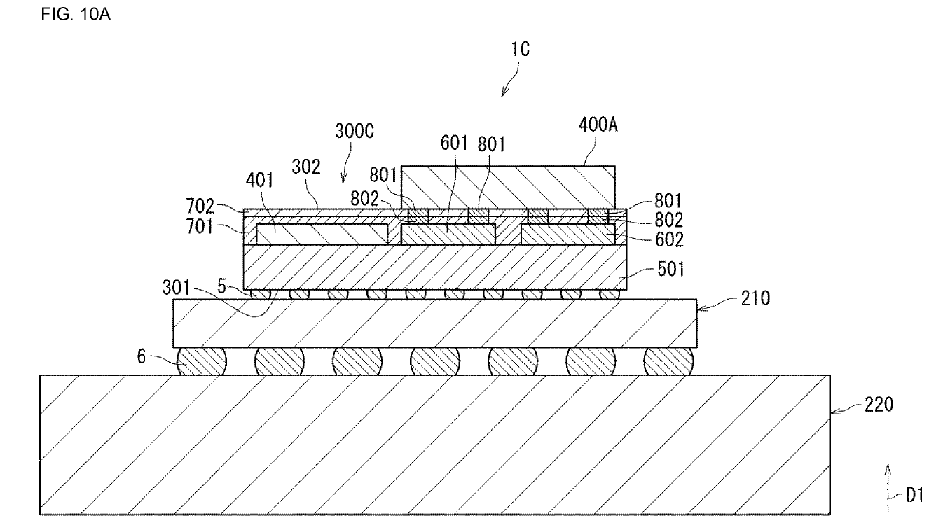

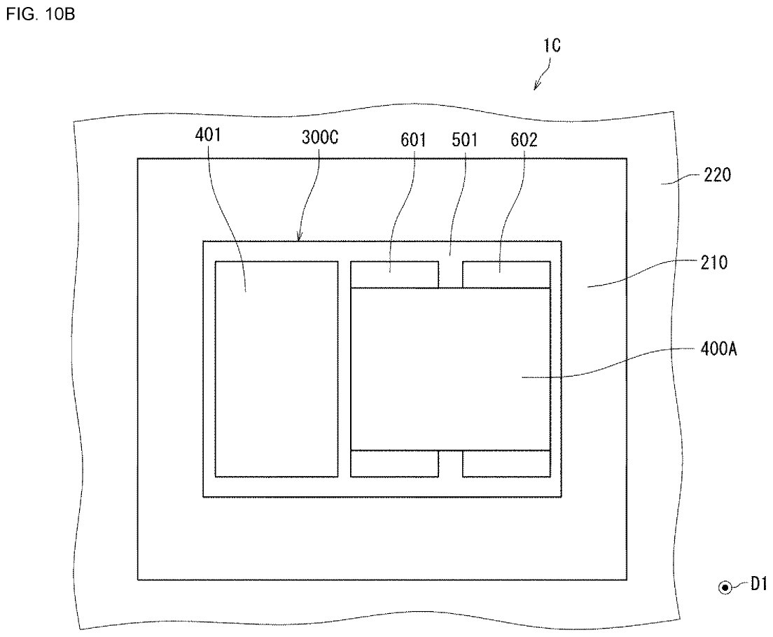

FIG. 9 is a simplified sectional view illustrating a second modification of a stacked semiconductor package. As illustrated in FIG. 9, a stacked semiconductor package 1B of the second modification is different from the stacked semiconductor package 1A of FIG. 8 in the configuration of a three-dimensional device 300B and in including components other than the three-dimensional device 300B. The remaining configuration is the same as that of the first modification, and hence the description thereof is omitted.

As illustrated in FIG. 9, the three-dimensional device 300B includes the single inductor component 501, the single capacitor component 601, and the single integrated circuit component 401. The inductor component 501, the capacitor component 601, and the integrated circuit component 401 are placed in order in the first direction D1. The capacitor component 601 corresponds to an example of “first passive component” in the claims, and the inductor component 501 corresponds to an example of “second passive component” in the claims.

A first major surface 501a, which faces the capacitor component 601, of the inductor component 501 and a first major surface 601a, which faces the inductor component 501, of the capacitor component 601, each include a flat surface. The flat surface of the inductor component 501 and the flat surface of the capacitor component 601 are bonded together while being in contact with each other. This bonding is direct bonding using the flat surfaces of the corresponding components as described in the first embodiment. Similarly, bonding between the capacitor component 601 and the integrated circuit component 401 is direct bonding using the flat surfaces of the corresponding components.

With the configuration described above, since the flat surface of the inductor component 501 and the flat surface of the capacitor component 601 are bonded together while being in contact with each other, the thickness of the three-dimensional device 300B can be reduced so that a reduction in the thickness of the stacked semiconductor package 1B can be achieved. Note that, at this time, it is only necessary that the three-dimensional device includes a plurality of passive components.

The stacked semiconductor package 1B includes a mounting integrated circuit component 400A and a mounting inductor component 500A. Here, a mounting component refers to a component that is not directly bonded via its flat surface. To be specific, the mounting integrated circuit component 400A and the mounting inductor component 500A are mounted on the first substrate 210. The mounting integrated circuit component 400A and the mounting inductor component 500A are connected to the first major surface 211 of the first substrate 210 with the first connection members 5 interposed therebetween.

With the configuration described above, since the integrated circuit component 400A and the inductor component 500A other than the three-dimensional device 300B are provided on the same first major surface 211 of the first substrate 210, the degree of integration of the package can be increased and parasitic components can be reduced.

### Second Embodiment

Configuration of Stacked Semiconductor Package 1C

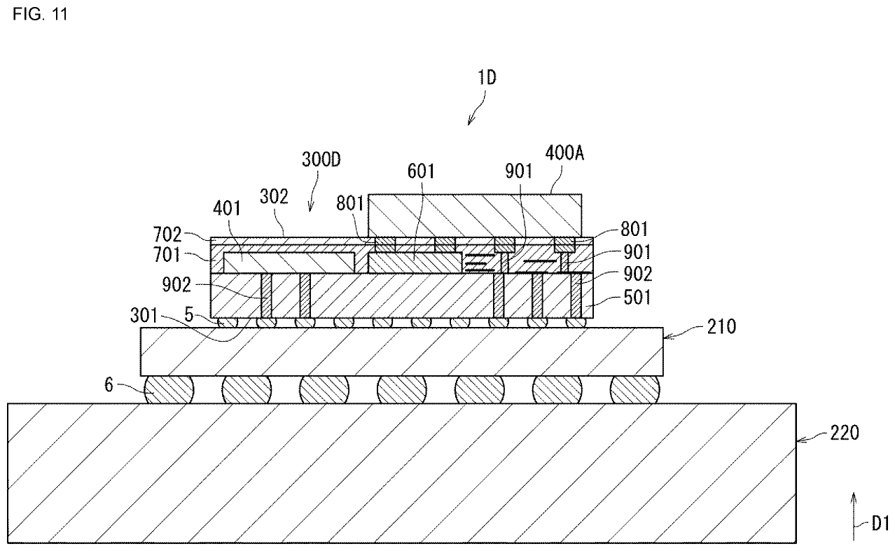

FIG. 10A is a simplified sectional view illustrating a second embodiment of a stacked semiconductor package. FIG. 10B is a simplified plan view illustrating the second embodiment of the stacked semiconductor package. Note that, as a matter of convenience, in FIG. 10B, the illustrations of insulating members are omitted.

As illustrated in FIG. 10A and FIG. 10B, a stacked semiconductor package 1C of the second embodiment is different from the stacked semiconductor package 1 of FIG. 1 in the configuration of a three-dimensional device 300C and in including components other than the three-dimensional device 300C. The remaining configuration is the same as that of the first embodiment, and hence the description thereof is omitted.

As illustrated in FIG. 10A and FIG. 10B, the three-dimensional device 300C includes the integrated circuit component 401, the inductor component 501, the first capacitor component 601, the second capacitor component 602, a first insulating member 701, and a second insulating member 702.

The integrated circuit component 401, the first capacitor component 601, and the second capacitor component 602 are stacked on the same upper surface of the inductor component 501. Bonding between the integrated circuit component 401 and the inductor component 501, bonding between the first capacitor component 601 and the inductor component 501, and bonding between the second capacitor component 602 and the inductor component 501 are each direct bonding using the flat surfaces of the corresponding components as described in the first embodiment.

The first insulating member 701 is provided on the upper surface of the inductor component 501 so as to at least partially cover the integrated circuit component 401, the first capacitor component 601, and the second capacitor component 602. With this, the first insulating member 701 can protect the components from moisture and mechanical stress. Further, a wire can be further provided on the first insulating member 701 to increase the number of stacked layers, which allows wire routing, with the result that the degree of freedom in circuit design can be improved.

The first insulating member 701 is made of, for example, an epoxy-based resin, a phenol-based resin, a polyimide-based resin, or a liquid crystal polymer-based resin, or a composite material containing an inorganic filler and these resins or the like. Alternatively, the first insulating member 701 is obtained by CVD, a deposition method, or the like using an inorganic substance such as Si, SiO₂, or SiN.

The second insulating member 702 is provided on the upper surface of the first insulating member 701. The second insulating member 702 is made of, for example, a material similar to that for the first insulating member 701.

The three-dimensional device 300C further includes electrical connection portions 801 on the second major surface 302 of the three-dimensional device 300C. To be specific, the first major surface 301 includes the lower surface of the inductor component 501, and the second major surface 302 includes the upper surface of the second insulating member 702. The plurality of electrical connection portions 801 are provided so as to penetrate the second insulating member 702. The electrical connection portion 801 is, for example, an external terminal. The plurality of electrical connection portions 801 are electrically connected to one of the first capacitor component 601 and the second capacitor component 602 with a plurality of via portions 802 interposed therebetween. The via portions 802 are provided in the first insulating member 701.

With the configuration described above, since other components can be stacked on the electrical connection portions 801 while being electrically connected to the electrical connection portions 801, the number of stacked layers can be increased, with the result that the degree of freedom in stacking and the degree of freedom in circuit design can be improved. Note that, the electrical connection portions 801 may be provided on at least one of the first major surface 301 and the second major surface 302.

It is preferred that the stacked semiconductor package 1C further includes the mounting integrated circuit component 400A. To be specific, the mounting integrated circuit component 400A is mounted on the second insulating member 702. The mounting integrated circuit component 400A is connected to the upper surface of the second insulating member 702 with the electrical connection portions 801 interposed therebetween. With this, since the integrated circuit component 400A other than the three-dimensional device 300C is included, the degree of integration of the package can be increased and parasitic components can be reduced.

Modification

FIG. 11 is a simplified sectional view illustrating a modification of a stacked semiconductor package. As illustrated in FIG. 11, a stacked semiconductor package 1D of the modification is different from the stacked semiconductor package 1C of FIG. 10A in the configuration of a three-dimensional device 300D. The remaining configuration is the same as that of the second embodiment, and hence the description thereof is omitted.

As illustrated in FIG. 11, the three-dimensional device 300D is different from the three-dimensional device 300C of FIG. 10A in not including the second capacitor component 602 and including first conductive wires 901 and second conductive wires 902. That is, the three-dimensional device 300D includes the integrated circuit component 401, the inductor component 501, the capacitor component 601, the first insulating member 701, the second insulating member 702, the plurality of first conductive wires 901, and the plurality of second conductive wires 902.

The first insulating member 701 is stacked on the same layer as the integrated circuit component 401 and the capacitor component 601. The first conductive wires 901 penetrate the first insulating member 701. With this, the degree of freedom in circuit design can be improved. Further, since the first conductive wire 901 penetrates the first insulating member 701, the first conductive wire 901 can be easily formed.

The first conductive wire 901 is made of, for example, Cu or an alloy containing Cu. The first conductive wire 901 preferably has a larger cross-sectional area than the front-end-of-line (FEOL) wire of a semiconductor integrated circuit component has. The first conductive wire 901 more preferably has a larger cross-sectional area than the back-end-of-line (BEOL) wire of a semiconductor integrated circuit component has. By using Cu, which is a relatively inexpensive material, as the material for the first conductive wire 901 and employing a rough process node for the first conductive wire 901, the first conductive wire 901 can be formed inexpensively. The thickness of the first conductive wire 901 is equal to or more than the thickness of the integrated circuit component 401 or the thickness of the capacitor component 601, and is equal to or less than the thickness of the first insulating member 701.

The second conductive wires 902 penetrate the inductor component 501 without being connected to the inductor elements of the inductor component 501. The inductor elements include a coil. With this, electrical signals can be transmitted/received through the second conductive wires 902 without using the inductor elements so that the degree of integration can be improved.

The material for the second through wire 902 is, for example, a material similar to that for the first conductive wire 901. The second conductive wire 902 preferably has a larger cross-sectional area than the FEOL wire of a semiconductor integrated circuit component has. The second conductive wire 902 more preferably has a larger cross-sectional area than the BEOL wire of a semiconductor integrated circuit component has. The thickness of the second conductive wire 902 is equal to or more than the thickness of the inductor component 501. Note that, the second conductive wires may penetrate passive components other than the inductor component 501 without being connected to the passive elements of the other passive components.

The first conductive wires 901 are electrically connected to some of the second conductive wires 902. The mounting integrated circuit component 400A is electrically connected to the first substrate 210 with the first conductive wires 901 and some of the second conductive wires 902 interposed therebetween. The integrated circuit component 401 is electrically connected to the first substrate 210 with the remaining second conductive wires 902 interposed therebetween.

### Third Embodiment

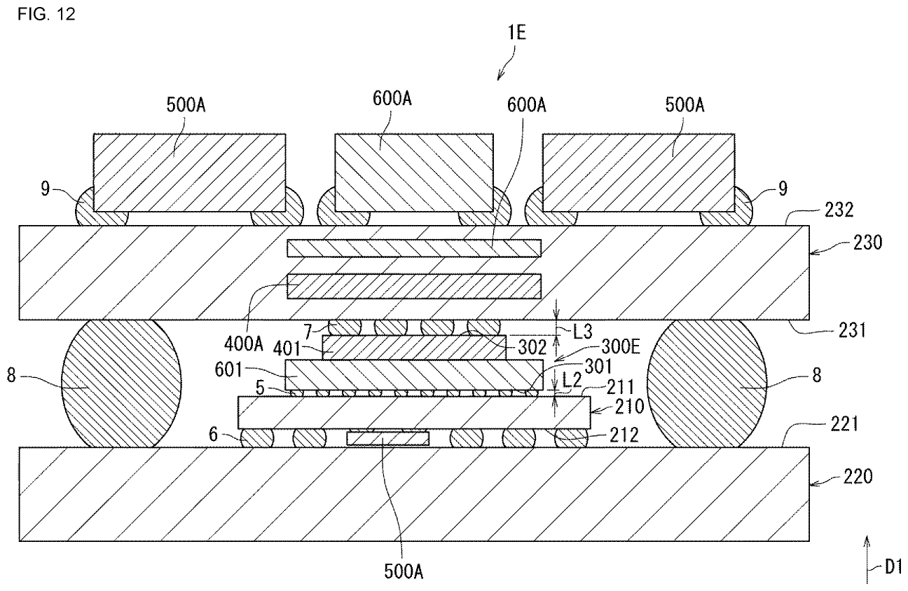

FIG. 12 is a simplified sectional view illustrating a third embodiment of a stacked semiconductor package. As illustrated in FIG. 12, a stacked semiconductor package 1E of the third embodiment is different from the stacked semiconductor package 1 of FIG. 1 in the configuration of a three-dimensional device 300E and in including a third substrate 230. The remaining configuration is the same as that of the first embodiment, and hence the description thereof is omitted.

As illustrated in FIG. 12, the three-dimensional device 300E includes the integrated circuit component 401 and the capacitor component 601. The integrated circuit component 401 is stacked on the upper surface of the capacitor component 601. Bonding between the integrated circuit component 401 and the capacitor component 601 is direct bonding using the flat surfaces of the corresponding components as described in the first embodiment.

The stacked semiconductor package 1E further includes the third substrate 230. The third substrate 230 is stacked in the first direction D1 with respect to the three-dimensional device 300E. A first major surface 231, which faces the three-dimensional device 300E, of the third substrate 230 and the second major surface 302, which faces the third substrate 230, of the three-dimensional device 300E are separated from each other and connected to each other with third connection members 7 interposed therebetween. The third connection member 7 is a material like the first connection member 5.

A third distance L3 between the first major surface 231 of the third substrate 230 and the second major surface 302 of the three-dimensional device 300E is larger than the second distance L2 between the first major surface 211 of the first substrate 210 and the first major surface 301 of the three-dimensional device 300E. With this, the circuit system can be increased in size so that the degree of freedom in circuit design can be improved. The third distance L3 is determined by a method similar to that for the first distance L1 or the second distance L2. The third distance L3 is, for example, 300 μm.

The third substrate 230 is configured like the second substrate 220. That is, the design accuracy of the third substrate 230 is lower than that of the first substrate 210. The first major surface 231 of the third substrate 230 is connected to the first major surface 221 of the second substrate 220 with fourth connection members 8 interposed therebetween. On a second major surface 232 of the third substrate 230, the mounting inductor components 500A and a mounting capacitor component 600A are mounted with fifth connection members 9 interposed therebetween. The fifth connection member 9 is a material like the first connection member 5. Inside the third substrate 230, the mounting integrated circuit component 400A and the mounting capacitor component 600A are incorporated.

It is preferred that the three-dimensional device 300E further includes the electrical connection portions 801 of the second embodiment on each of the first major surface 301 and the second major surface 302 of the three-dimensional device 300E. With this, electrical signals can be transmitted/received from the superior surface and inferior surface of the three-dimensional device 300E so that the degree of freedom in circuit design can be improved.

Note that, the present disclosure is not limited to the embodiments described above, and design changes can be made within the scope not departing from the gist of the present disclosure. For example, the features of the respective first to third embodiments may be variously combined with each other.
<1> A stacked semiconductor package including: a first substrate; a three-dimensional device stacked in a first direction with respect to the first substrate; and a first connection member for connecting the first substrate to the three-dimensional device. The three-dimensional device includes a plurality of components each of which includes a semiconductor integrated circuit component and a passive component stacked in the first direction. A first major surface, which faces the three-dimensional device, of the first substrate and a first major surface, which faces the first substrate, of the three-dimensional device are connected to each other with the first connection member interposed therebetween while being separated from each other. A first major surface, which faces the passive component, of the semiconductor integrated circuit component and a first major surface, which faces the semiconductor integrated circuit component, of the passive component each include a flat surface. The flat surface of the semiconductor integrated circuit component and the flat surface of the passive component are bonded together while being in contact with each other.
<2> The stacked semiconductor package according to <1>, in which an area of the flat surface of the semiconductor integrated circuit component is larger than half of an area of the first major surface of the semiconductor integrated circuit component, and an area of the flat surface of the passive component is larger than half of an area of the first major surface of the passive component.
<3> The stacked semiconductor package according to <1> or <2>, in which the flat surface of the semiconductor integrated circuit component and the flat surface of the passive component are each made of an inorganic substance.
<4> The stacked semiconductor package according to any one of <1> to <3>, in which the three-dimensional device includes a plurality of the semiconductor integrated circuit components, and the plurality of semiconductor integrated circuit components are placed in order in the first direction or a direction orthogonal to the first direction.
<5> The stacked semiconductor package according to any one of <1> to <4>, in which the three-dimensional device includes a plurality of the passive components, and the plurality of passive components are placed in order in the first direction or a direction orthogonal to the first direction.
<6> The stacked semiconductor package according to any one of <1> to <5>, further including a second substrate; and a second connection member. the first substrate is stacked in the first direction with respect to the second substrate. A second major surface, which faces the second substrate, of the first substrate and a first major surface, which faces the first substrate, of the second substrate are separated from each other and connected to each other with the second connection member interposed therebetween. Also, a distance between the second major surface of the first substrate and the first major surface of the second substrate is larger than a distance between the first major surface of the first substrate and the first major surface of the three-dimensional device.
<7> The stacked semiconductor package according to any one of <1> to <6>, in which the three-dimensional device includes at least one of the semiconductor integrated circuit components and at least one of the passive components. Also, of all the semiconductor integrated circuit components and all the passive components, a plurality of components are stacked on a same layer. In addition, the respective plurality of components have a same thickness in the first direction.
<8> The stacked semiconductor package according to any one of <1> to <6>, in which the three-dimensional device includes at least one of the semiconductor integrated circuit components and at least one of the passive components. Also, of all the semiconductor integrated circuit components and all the passive components, a plurality of components are stacked on a top layer in the first direction. In addition, of the plurality of components on the top layer, at least two components have different thicknesses in the first direction.
<9> The stacked semiconductor package according to any one of <1> to <8>, in which the three-dimensional device includes at least one of the semiconductor integrated circuit components and at least one of the passive components. Also, of all the semiconductor integrated circuit components and all the passive components, a component closest to the first substrate in the first direction has an area of a surface vertical to the first direction that is larger than an area of a surface vertical to the first direction of each of the other components.
<10> The stacked semiconductor package according to any one of <1> to <9>, in which the three-dimensional device includes at least one of the semiconductor integrated circuit components and at least one of the passive components. Also, an area of a surface vertical to the first direction of at least one of all the passive components is smaller than an area of a surface vertical to the first direction of at least one of all the semiconductor integrated circuit components.
<11> The stacked semiconductor package according to any one of <1> to <10>, in which the three-dimensional device includes at least one of the semiconductor integrated circuit components and at least one of the passive components. Also, an area of a surface of at least one of all the passive components is larger than an area of a surface of at least one of all the semiconductor integrated circuit components.
<12> The stacked semiconductor package according to any one of <1> to <11>, in which at least one of the passive components is an inductor component, and the inductor component has a larger area of a surface vertical to the first direction than at least one of the semiconductor integrated circuit components.
<13> The stacked semiconductor package according to any one of <1> to <12>, in which the three-dimensional device further includes a second passive component, and a first passive component of the passive components and the second passive component are placed in order in the first direction. Also, a first major surface, which faces the second passive component, of the first passive component and a first major surface, which faces the first passive component, of the second passive component each include a flat surface, and the flat surface of the first passive component and the flat surface of the second passive component are bonded together while being in contact with each other.
<14> The stacked semiconductor package according to any one of <1> to <13>, in which the three-dimensional device further includes an insulating member for at least partially covering the semiconductor integrated circuit component and the passive component.
<15> The stacked semiconductor package according to any one of <1> to <14>, further including a third substrate; and a third connection member. The third substrate is stacked in the first direction with respect to the three-dimensional device, and a first major surface, which faces the three-dimensional device, of the third substrate and a second major surface, which faces the third substrate, of the three-dimensional device are separated from each other and connected to each other with the third connection member interposed therebetween. Also, a distance between the first major surface of the third substrate and the second major surface of the three-dimensional device is larger than a distance between the first major surface of the first substrate and the first major surface of the three-dimensional device.
<16> A method of manufacturing a stacked semiconductor package, the method including forming a three-dimensional device by bonding a semiconductor integrated circuit component that has a flat surface to a passive component that has a flat surface while holding the flat surfaces in contact with each other; and connecting a first major surface of the three-dimensional device to a first major surface of a first substrate with a connection member interposed therebetween while separating the first major surfaces from each other.

What is claimed is:

1. A stacked semiconductor package comprising:
a first substrate;
a three-dimensional device stacked in a first direction with respect to the first substrate; and
a first connection member for connecting the first substrate to the three-dimensional device, wherein
the three-dimensional device includes a plurality of components each of which includes a semiconductor integrated circuit component and a passive component stacked in the first direction,
a first major surface, which faces the three-dimensional device, of the first substrate and a first major surface, which faces the first substrate, of the three-dimensional device are connected to each other with the first connection member interposed therebetween while being separated from each other,
a first major surface, which faces the passive component, of the semiconductor integrated circuit component, and a first major surface, which faces the semiconductor integrated circuit component, of the passive component, each include a flat surface, and
the flat surface of the semiconductor integrated circuit component and the flat surface of the passive component are bonded together while being in contact with each other.

2. The stacked semiconductor package according to claim 1, wherein
an area of the flat surface of the semiconductor integrated circuit component is larger than half of an area of the first major surface of the semiconductor integrated circuit component, and
an area of the flat surface of the passive component is larger than half of an area of the first major surface of the passive component.

3. The stacked semiconductor package according to claim 1, wherein
the flat surface of the semiconductor integrated circuit component and the flat surface of the passive component each include an inorganic substance.

4. The stacked semiconductor package according to claim 1, wherein
the three-dimensional device includes a plurality of the semiconductor integrated circuit components, and
the plurality of semiconductor integrated circuit components are configured in order in the first direction or a direction orthogonal to the first direction.

5. The stacked semiconductor package according to claim 1, wherein
the three-dimensional device includes a plurality of the passive components, and
the plurality of passive components are configured in order in the first direction or a direction orthogonal to the first direction.

6. The stacked semiconductor package according to claim 1, further comprising:
a second substrate; and
a second connection member, wherein
the first substrate is stacked in the first direction with respect to the second substrate,
a second major surface, which faces the second substrate, of the first substrate, and a first major surface, which faces the first substrate, of the second substrate, are separated from each other and connected to each other with the second connection member interposed therebetween, and
a distance between the second major surface of the first substrate and the first major surface of the second substrate is larger than a distance between the first major surface of the first substrate and the first major surface of the three-dimensional device.

7. The stacked semiconductor package according to claim 1, wherein
the three-dimensional device includes at least one of the semiconductor integrated circuit components and at least one of the passive components,
of all the semiconductor integrated circuit components and all the passive components, a plurality of components are stacked on a same layer, and
the respective plurality of components have a same thickness in the first direction.

8. The stacked semiconductor package according to claim 1, wherein
the three-dimensional device includes at least one of the semiconductor integrated circuit components and at least one of the passive components,
of all the semiconductor integrated circuit components and all the passive components, a plurality of components are stacked on a top layer in the first direction, and
of the plurality of components on the top layer, at least two components have different thicknesses in the first direction.

9. The stacked semiconductor package according to claim 1, wherein
the three-dimensional device includes at least one of the semiconductor integrated circuit components and at least one of the passive components, and
of all the semiconductor integrated circuit components and all the passive components, a component closest to the first substrate in the first direction has an area of a surface vertical to the first direction that is larger than an area of a surface vertical to the first direction of each of the other components.

10. The stacked semiconductor package according to claim 1, wherein
the three-dimensional device includes at least one of the semiconductor integrated circuit components and at least one of the passive components, and
an area of a surface vertical to the first direction of at least one of all the passive components is smaller than an area of a surface vertical to the first direction of at least one of all the semiconductor integrated circuit components.

11. The stacked semiconductor package according to claim 1, wherein
the three-dimensional device includes at least one of the semiconductor integrated circuit components and at least one of the passive components, and
an area of a surface vertical to the first direction of at least one of all the passive components is larger than an area of a surface vertical to the first direction of at least one of all the semiconductor integrated circuit components.

12. The stacked semiconductor package according to claim 1, wherein
at least one of the passive components is an inductor component, and
the inductor component has a larger area of a surface vertical to the first direction than at least one of the semiconductor integrated circuit components has.

13. The stacked semiconductor package according to claim 1, wherein
the three-dimensional device further includes a second passive component,
a first passive component of the passive components and the second passive component are placed in order in the first direction,
a first major surface, which faces the second passive component, of the first passive component, and a first major surface, which faces the first passive component, of the second passive component, each include a flat surface, and
the flat surface of the first passive component and the flat surface of the second passive component are bonded together while being in contact with each other.

14. The stacked semiconductor package according to claim 1, wherein
the three-dimensional device further includes an insulating member for at least partially covering the semiconductor integrated circuit component and the passive component.

15. The stacked semiconductor package according to claim 1, further comprising:
a third substrate; and
a third connection member, wherein
the third substrate is stacked in the first direction with respect to the three-dimensional device,
a first major surface, which faces the three-dimensional device, of the third substrate, and a second major surface, which faces the third substrate, of the three-dimensional device, are separated from each other and connected to each other with the third connection member interposed therebetween, and
a distance between the first major surface of the third substrate and the second major surface of the three-dimensional device is larger than a distance between the first major surface of the first substrate and the first major surface of the three-dimensional device.

16. The stacked semiconductor package according to claim 2, wherein
the flat surface of the semiconductor integrated circuit component and the flat surface of the passive component each include an inorganic substance.

17. The stacked semiconductor package according to claim 2, wherein
the three-dimensional device includes a plurality of the semiconductor integrated circuit components, and
the plurality of semiconductor integrated circuit components are configured in order in the first direction or a direction orthogonal to the first direction.

18. The stacked semiconductor package according to claim 2, wherein
the three-dimensional device includes a plurality of the passive components, and
the plurality of passive components are configured in order in the first direction or a direction orthogonal to the first direction.

19. The stacked semiconductor package according to claim 2, further comprising:
a second substrate; and
a second connection member, wherein
the first substrate is stacked in the first direction with respect to the second substrate,
a second major surface, which faces the second substrate, of the first substrate, and a first major surface, which faces the first substrate, of the second substrate, are separated from each other and connected to each other with the second connection member interposed therebetween, and
a distance between the second major surface of the first substrate and the first major surface of the second substrate is larger than a distance between the first major surface of the first substrate and the first major surface of the three-dimensional device.

20. A method of manufacturing a stacked semiconductor package, the method comprising:
forming a three-dimensional device by bonding a semiconductor integrated circuit component that has a flat surface to a passive component that has a flat surface while holding the flat surfaces in contact with each other; and
connecting a first major surface of the three-dimensional device to a first major surface of a first substrate with a connection member interposed therebetween while separating the first major surfaces from each other.
